(19) United States
(12) Patent Application Publication
(10) Pub. No.: US 2026/0134900 A1
(43) Pub. Date: May 14, 2026

(54) MEMORY CIRCUIT AND METHOD OF OPERATING SAME

(71) Applicant: TAIWAN SEMICONDUCTOR MANUFACTURING COMPANY, LTD., Hsinchu (TW)

(72) Inventor: Tomohiko YANO, Hsinchu (TW)

(21) Appl. No.: 18/947,475

(22) Filed: Nov. 14, 2024

(51) Int. Cl. G11C 7/12; G11C 7/08; G11C 7/18

(52) U.S. Cl. CPC G11C 7/12; G11C 7/08; G11C 7/18

(57) ABSTRACT

A memory circuit includes a memory cell, a bit line, a bit line bar, a pass-gate transistor coupled to the memory cell and the bit line, a sense amplifier coupled to the bit line, the bit line bar and the pass-gate transistor, and a pre-charge circuit coupled to the first node, and configured to pre-charge the first node to a pre-charge voltage in response to a pre-charge control signal. The sense amplifier includes a first path between the bit line and the bit line bar. The first path includes a first isolation transistor configured to receive an isolation control signal, and being coupled between the bit line and a first node, and a first inverter configured to receive a sense amplifier enable signal, and being coupled between a second node and a third node.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory circuit, in accordance with some embodiments.

FIG. 2 is a circuit diagram of a memory circuit, in accordance with some embodiments.

FIG. 3 is a timing diagram of waveforms of a memory circuit, such as the memory circuit in FIG. 2, in accordance with some embodiments.

FIG. 4 is a timing diagram of waveforms of a memory circuit, such as the memory circuit in FIG. 2, in accordance with some embodiments.

FIG. 5 is a circuit diagram of a memory circuit, in accordance with some embodiments.

FIG. 6 is a timing diagram of waveforms of a memory circuit, such as the memory circuit in FIG. 5, in accordance with some embodiments.

FIG. 7 is a timing diagram of waveforms of a memory circuit, such as the memory circuit in FIG. 5, in accordance with some embodiments.

FIG. 8 is a circuit diagram of a circuit usable in FIGS. 1, 2 and 5, in accordance with some embodiments.

FIGS. 9A-9B are a flowchart of a method of operating a circuit, in accordance with some embodiments.

FIGS. 10A-10B are a flowchart of a method of operating a circuit, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a memory circuit includes a memory cell, a bit line, and a bit line bar.

In some embodiments, the memory circuit further includes a pass-gate transistor coupled to the memory cell and the bit line.

In some embodiments, the memory circuit further includes a sense amplifier. In some embodiments, the sense amplifier is coupled to the bit line, the bit line bar and the pass-gate transistor.

In some embodiments, the sense amplifier includes a first path. In some embodiments, the first path is between the bit line and the bit line bar.

In some embodiments, the first path includes a first isolation transistor. In some embodiments, the first isolation transistor is configured to receive an isolation control signal. In some embodiments, the first isolation transistor is coupled between the bit line and a first node.

In some embodiments, the first path further includes a first inverter. In some embodiments, the first inverter is configured to receive a sense amplifier enable signal. In some embodiments, the first inverter is coupled between a second node and a third node.

In some embodiments, the first path further includes a first capacitor. In some embodiments, the first capacitor is coupled between the second node and one of the first node or the first isolation transistor.

In some embodiments, the first path further includes a second isolation transistor. In some embodiments, the second isolation transistor is configured to receive the isolation control signal. In some embodiments, the second isolation transistor is coupled between the third node and the bit line bar.

In some embodiments, the memory circuit further includes a pre-charge circuit coupled to the first node. In some embodiments, the pre-charge circuit is configured to pre-charge the first node to a pre-charge voltage in response to a pre-charge control signal.

In some embodiments, a random input offset voltage is a large noise component for bit-line sense amplifiers thereby affecting the accuracy of one or more read operations of the memory cell. In some embodiments, the random input offset voltage is due to process variations.

In some embodiments, by including the first isolation transistor between the first capacitor and the first bit line, the random offset of the input voltage to the memory circuit can be cancelled while improving the accuracy and speed of one or more read operations performed by the memory circuit and/or the sense amplifier compared with other approaches.

No time penalty for offset canceling operation. No degradation of read latency.

Input signal amplitude (Vsin) becomes 2× larger

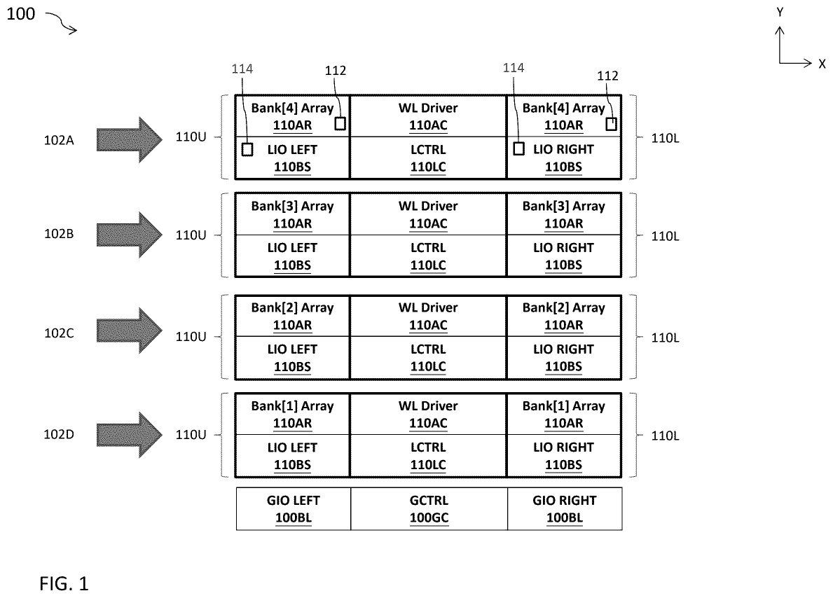

FIG. 1 is a block diagram of a memory circuit 100, in accordance with some embodiments.

FIG. 1 is simplified for the purpose of illustration. In some embodiments, memory circuit 100 includes various elements in addition to those depicted in FIG. 1 or is otherwise arranged so as to perform the operations discussed below.

Memory circuit 100 is an IC that includes memory partitions 102A-102D, a global control circuit 100GC and global input output (GIO) circuits 100BL.

Each memory partition 102A-102D includes memory banks 110U and 110L adjacent to a word line (WL) driver circuit 110AC and a local control circuit 110LC. Each memory bank 110U and 110L includes a memory cell array 110AR and a local input output (LIO) circuit 110BS.

A memory partition, e.g., a memory partition 102A-102D, is a portion of memory circuit 100 that includes a subset of memory devices (not shown in FIG. 1) and adjacent circuits configured to selectively access the subset of memory devices in program and read operations. In the embodiment depicted in FIG. 1, memory circuit 100 includes a total of four partitions. In some embodiments, memory circuit 100 includes a total number of partitions greater or fewer than four.

GIO circuit 100BL is a circuit configured to control access to one or more electrical paths, e.g., bit lines, to each memory device of the corresponding memory bank 110U or 110L of each memory partition 102A-102D, e.g., by generating one or more bit line signals. In some embodiments, GIO circuit 100BL includes a global bit line driver circuit. In some embodiments, GIO circuit 100BL is coupled to each memory bank 110U and 110L by a corresponding global bit line (not shown).

Global control circuit 100GC is a circuit configured to control some or all of program and read operations on each memory partition 102A-102D, e.g., by generating and/or outputting one or more control and/or enable signals.

In some embodiments, global control circuit 100GC includes one or more analog circuits configured to interface with memory partitions 102A-102D, cause data to be programmed in one or more memory devices, and/or use data received from one or more memory devices in one or more circuit operations. In some embodiments, global control circuit 100GC includes one or more global address decode or pre-decoder circuits configured to output one or more address signals to the WL driver circuit 110AC of each memory partition 102A-102D.

Each WL driver circuit 110AC is configured to generate word line signals on corresponding word lines WL. In some embodiments, each WL driver circuit 110AC is configured to output word line signals on corresponding word lines WL to the adjacent memory banks 110U and 110L of the corresponding memory partition 102A-102D.

Each local control circuit 110LC is an electronic circuit configured to receive one or more address signals. Each local control circuit 110LC is configured to generate signals corresponding to adjacent subsets of memory devices identified by the one or more address signals. In some embodiments, the adjacent subsets of memory devices correspond to columns of memory devices. In some embodiments, each local control circuit 110LC is configured to generate each signal as a complementary pair of signals. In some embodiments, each local control circuit 110LC is configured to output the signals to corresponding word line driver circuits within the adjacent WL driver circuit 110AC of the corresponding memory partition 102A-102D. In some embodiments, the local control circuit 110DC includes a bank decoder circuit.

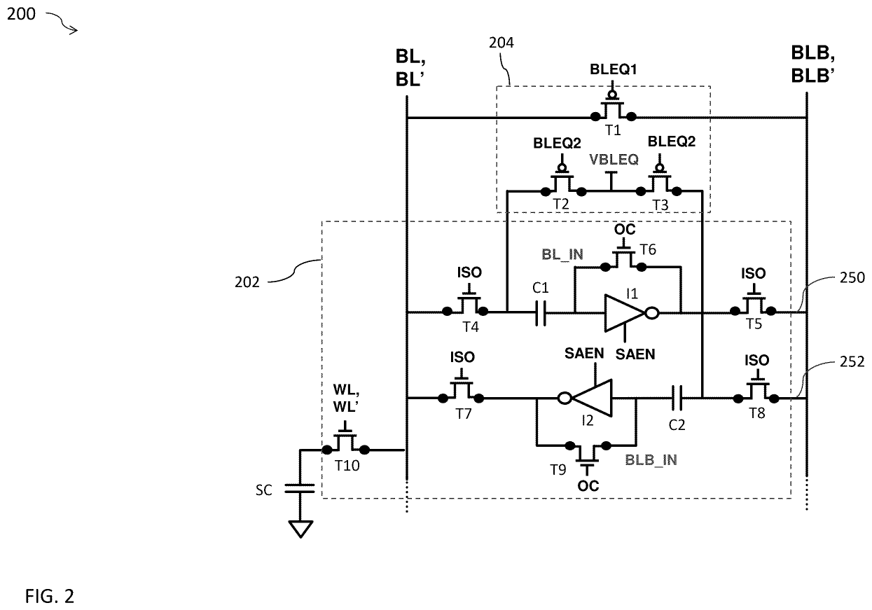

Each LIO circuit 110BS is configured to selectively access one or more bit lines (shown in FIG. 2) coupled to adjacent subsets of memory devices of the corresponding memory cell array 110AR responsive to GIO circuit 100BL, e.g., based on one or more BL control signals. In some embodiments, the adjacent subsets of memory devices correspond to rows of memory devices. In some embodiments, the LIO circuit 110BS includes a bit line selection circuit.

Each LIO circuit 110BS includes one or more circuits 114. In some embodiments, each circuit 114 includes a circuit configured as a sense amplifier circuit. For example, during a read operation, circuit 114 is a sense amplifier circuit that is configured to read data from at least one memory cell 112 in a corresponding column of memory cells in the corresponding memory cell array 110AR, and/or to restore data to the at least one memory cell 112 in the corresponding column of memory cells in the corresponding memory cell array 110AR, in accordance with some embodiments. In some embodiments, each circuit 114 includes a circuit configured as a write in latch. For example, during a write operation, circuit 114 is a write-in latch circuit that is configured to write data into at least one memory cell 112 in a corresponding column of memory cells in the corresponding memory cell array 110AR, in accordance with some embodiments. In some embodiments, each circuit 114 in LIO circuit 110BS is coupled to a corresponding column of memory devices 112 in memory cell array 110AR. In some embodiments, GIO circuit 100BL includes one or more circuits 114 (not shown).

Each memory bank 110U and 110L includes the corresponding memory cell array 110AR including memory cells or memory devices 112 configured to be accessed in program/write and read operations by the adjacent LIO circuit 110BS and the adjacent WL driver circuit 110AC.

Each memory cell array 110AR includes an array of memory devices 112 having N rows and M columns, where M and N are positive integers. The rows of cells in memory cell array 102 are arranged in a first direction X. The columns of cells in memory cell array 102 are arranged in a second direction Y. The second direction Y is different from the first direction X. In some embodiments, the second direction Y is perpendicular to the first direction X. In some embodiments, each memory cell array 110AR is divided into an upper region and a lower region (not shown). In some embodiments, each column of memory devices 112 in memory cell array 110AR is coupled to a corresponding circuit 114 in LIO circuit 110BS.

Memory device 112 is shown in memory bank 110U and 110L of memory partition 102A. For ease of illustration, memory device 112 is not shown in memory bank 110U and 110L of memory partitions 102B, 102C and 102D.

Memory device 112 is an electrical, electromechanical, electromagnetic, or other device configured to store bit data represented by logical states. At least one logical state of memory device 112 is capable of being programmed in a write operation and detected in a read operation. In some embodiments, a logical state corresponds to a voltage level of an electrical charge stored in a given memory device 112. In some embodiments, a logical state corresponds to a physical property, e.g., a voltage, a current, a resistance or a magnetic orientation, of a component of a given memory device 112.

In some embodiments, memory device 112 includes one or more dynamic random access memory (DRAM) cells. Different types of memory cells in memory device 112 are within the contemplated scope of the present disclosure. In some embodiments, memory device 112 includes one or more single port (SP) static random access memory (SRAM) cells. In some embodiments, memory device 112 includes one or more dual port (DP) SRAM cells. In some embodiments, memory device 112 includes one or more multi-port SRAM cells. In some embodiments, memory device 112 includes one or more one-time programmable (OTP) memory devices such as electronic fuse (eFuse) or anti-fuse devices, flash memory devices, random-access memory (RAM) devices, resistive RAM devices, ferroelectric RAM devices, magneto-resistive RAM devices, erasable programmable read only memory (EPROM) devices, electrically erasable programmable read only memory (EEPROM) devices, or the like. In some embodiments, memory device 112 is an OTP memory device including one or more OTP memory cells.

Other configurations of memory circuit 100 are within the scope of the present disclosure.

FIG. 2 is a circuit diagram of a memory circuit 200, in accordance with some embodiments.

Memory circuit 200 is an embodiment of one column and one row of memory cells of memory cell array 110AR and circuit 114 of FIG. 1, and similar detailed description is therefore omitted. For example, memory circuit 200 illustrates a non-limiting example where a memory cell SC of memory circuit 200 is an embodiment of one column and one row of memory cells in memory cell array 110AR of FIG. 1, and sense amplifier circuit 202 of memory circuit 200 corresponds to circuit 114 of FIG. 1, and similar detailed description is therefore omitted. In some embodiments, memory cell SC of memory circuit 200 corresponds to memory cell 112 of FIG. 1, and similar detailed description is therefore omitted. In some embodiments, transistor T10 corresponds to one or more of circuit 114 of FIG. 1, WL driver circuit 110AC or local control circuit 110LC, and similar detailed description is therefore omitted. In some embodiments, sense amplifier circuit 202 of memory circuit 200 is useable in GIO circuit 100BL in FIG. 1 in a manner similar to circuit 114 of LIO circuit 110BS, and similar detailed description is therefore omitted.

Memory circuit 200 includes a memory cell SC, a sense amplifier circuit 202, a bit line BL, a bit line bar BLB, and a pre-charge and equalization circuit 204.

Memory cell SC is coupled to sense amplifier circuit 202. In some embodiments, memory cell SC is coupled to the bit line BL by transistor T10. In some embodiments, memory cell SC is coupled to a bit line bar BLB by a transistor, similar to transistor T10, and a bit line bar BLB.

Memory cell SC is a DRAM cell. Other types or numbers of memory cells in memory cell SC are within the contemplated scope of the present disclosure.

A first terminal of memory cell SC is coupled to a reference voltage supply VSS. A second terminal of memory cell SC is coupled to a drain/source of transistor T10. In some embodiments, memory cell SC is configured to store at least one bit of data as represented by one or more logical states (e.g., logically low state (e.g., logic 0) or a logically high state (e.g., logic 1)). In some embodiments, the first terminal of memory cell SC is an anode of a capacitor, and the second terminal of memory cell SC is a cathode of the capacitor. In some embodiments, the first terminal of memory cell SC is the cathode of the capacitor, and the second terminal of memory cell SC is the anode of the capacitor.

Other configurations of memory cell SC are within the scope of the present disclosure.

Sense amplifier circuit 202 is coupled to the memory cell SC, the bit line BL, the bit line bar BLB and the pre-charge and equalization circuit 204.

During a read operation of memory cell SC, sense amplifier circuit 202 is configured to sense or read data from memory cell SC, and is configured to output a data signal Q, in accordance with some embodiments. In some embodiments, the data signal Q corresponds to the data read from memory cell SC. In some embodiments, the data signal Q corresponds to the data stored in the memory cell SC. In some embodiments, during the read operation of memory cell SC, after the sense amplifier circuit 202 is configured to sense or read data from memory cell SC, the sense amplifier circuit 202 is further configured to write the data that was previously read from memory cell SC in the read operation by applying a voltage to the memory cell SC, thus recharging the capacitor in memory cell SC in a memory refresh operation.

In some embodiments, by the sense amplifier circuit 202 including less transistors or logic devices than other approaches, sense amplifier circuit 202 has less standby leakage than other approaches because fewer transistors or logic devices in sense amplifier circuit 202 results in a lower overall gate count than other approaches.

Sense amplifier circuit 202 comprises a transistor T4, a transistor T5, a transistor T6, a transistor T7, a transistor T8, a transistor T9, a transistor T10, a capacitor C1, a capacitor C2, an inverter I1 and an inverter I2.

In some embodiments, transistor T10 is not part of sense amplifier circuit 202, but is part of memory circuit 200 or 500. In some embodiments, transistor T10 is a pass gate transistor.

In some embodiments, at least one or more of transistors T4, T5, T6, T7, T8, T9 or T10 is an N-type transistor. In some embodiments, at least one or more of transistors T4, T5, T6, T7, T8, T9 or T10 is an N-type field effect transistor (NFET). In some embodiments, at least one or more of transistors T4, T5, T6, T7, T8, T9 or T10 is an N-type metal oxide semiconductor (NMOS) transistor.

A gate of transistor T10 is configured to receive a word line signal WL′. In some embodiments, the gate of transistor T10 is coupled to a word line WL. A drain/source of transistor T10 is coupled to memory cell SC. In some embodiments, transistor T10 is enabled or disabled in response to the word line signal WL′. In some embodiments, when enabled the transistor T10 electrically couples the memory cell SC and the bit line BL together.

Each of a source/drain of transistor T10, a drain/source of transistor T4, a drain/source of transistor T7, a drain/source of transistor T1 and the bit line BL are coupled to each other.

A gate of transistor T4 is configured to receive an isolation control signal ISO. In some embodiments, the gate of transistor T4 is coupled to a source of the isolation control signal ISO.

Each of a node ND1, a source/drain of transistor T4, a drain/source of transistor T2 and a first terminal of capacitor C1 are coupled to each other.

Each of a node ND2, a source/drain of transistor T6, a second terminal of capacitor C1 and an input terminal of inverter I1 are coupled to each other. In some embodiments, a signal BL_IN is a signal of node Nd2.

Transistor T6 and inverter I1 are coupled in parallel with each other. A gate of transistor T6 is configured to receive a control signal OC. In some embodiments, the gate of transistor T6 is coupled to a source of the control signal OC.

Inverter I1 is enabled or disabled by a sense amplifier enable signal SAEN. In some embodiments, when inverter I1 is enabled by a sense amplifier enable signal SAEN, then inverter I1 is configured to generate an inverted signal BL_IN′ in response to signal BL_IN. In some embodiments, signal BL_IN is inverted from inverted signal BL_IN′ and vice versa. In some embodiments, inverted signal BL_IN′ is a signal of a node Nd3. In some embodiments, when inverter I1 is disabled by the sense amplifier enable signal SAEN, then inverter I1 does not generate the inverted signal BL_IN′.

An input terminal of inverter I1 is configured to receive the signal BL_IN. An output terminal of inverter I1 is configured to output the inverted signal BL_IN′.

Each of a node ND3, a drain/source of transistor T6, an output terminal of inverter I1 and a source/drain of transistor T5 are coupled to each other.

A gate of transistor T5 is configured to receive the isolation control signal ISO. In some embodiments, the gate of transistor T5 is coupled to the source of the isolation control signal ISO.

Each of a drain/source of transistor T5, a drain/source of transistor T8, a source/drain of transistor T1 and the bit line bar BLB are coupled to each other.

A gate of transistor T8 is configured to receive the isolation control signal ISO. In some embodiments, the gate of transistor T8 is coupled to the source of the isolation control signal ISO.

Each of a node ND4, a source/drain of transistor T8, a drain/source of transistor T3 and a first terminal of capacitor C2 are coupled to each other.

Each of a node ND5, a source/drain of transistor T9, a second terminal of capacitor C2 and an input terminal of inverter I2 are coupled to each other. In some embodiments, a signal BLB_IN is a signal of node Nd5.

Transistor T9 and inverter I2 are coupled in parallel with each other. A gate of transistor T9 is configured to receive the control signal OC. In some embodiments, the gate of transistor T9 is coupled to the source of the control signal OC.

Inverter I2 is enabled or disabled by the sense amplifier enable signal SAEN. In some embodiments, when inverter I2 is enabled by the sense amplifier enable signal SAEN, then inverter I2 is configured to generate an inverted signal BLB_IN′ in response to signal BLB_IN. In some embodiments, signal BLB_IN is inverted from inverted signal BLB_IN′ and vice versa. In some embodiments, inverted signal BLB_IN′ is a signal of a node Nd6. In some embodiments, when inverter I2 is disabled by the sense amplifier enable signal SAEN, then inverter I2 does not generate the inverted signal BLB_IN′.

An input terminal of inverter I2 is configured to receive the signal BLB_IN. An output terminal of inverter I2 is configured to output the inverted signal BLB_IN′.

Each of a node ND6, a drain/source of transistor T9, an output terminal of inverter I2 and a source/drain of transistor T7 are coupled to each other.

A gate of transistor T7 is configured to receive the isolation control signal ISO. In some embodiments, the gate of transistor T7 is coupled to the source of the isolation control signal ISO.

In some embodiments, transistors T4 and T5, capacitor C1, inverter I1 and nodes Nd1, Nd2 and Nd3 are part of a first path 250. The first path 250 is coupled between the bit line BL and bit line bar BLB. In some embodiments, the first path 250 further includes transistor T6.

In some embodiments, transistors T7 and T8, capacitor C2, inverter I2 and nodes Nd4, Nd5 and Nd6 are part of a second path 252. The second path 252 is coupled between the bit line BL and bit line bar BLB. In some embodiments, the second path 252 further includes transistor T9.

Pre-charge and equalization circuit 204 is coupled to the bit line BL, the bit line bar BLB, the memory cell SC and the sense amplifier 202.

Pre-charge and equalization circuit 204 is configured to pre-charge and equalize a voltage of the bit line BL and a voltage of the bit line bar BLB to a voltage VBLEQ in response to at least one of a signal BLEQ1 or a signal BLEQ2.

In some embodiments, pre-charge and equalization circuit 204 is configured to pre-charge and equalize the voltage of the bit line BL and the voltage of the bit line bar BLB to the voltage VBLEQ prior to a read operation of memory cell SC. In some embodiments, pre-charge and equalization circuit 204 is configured to pre-charge the voltage of the bit line BL and the voltage of the bit line bar BLB to the voltage VBLEQ in response to signal BLEQ2. In some embodiments, pre-charge and equalization circuit 204 is configured to equalize the voltage of the bit line BL and the voltage of the bit line bar BLB to the voltage VBLEQ in response to signal BLEQ1.

In some embodiments, voltage VBLEQ is equal to a voltage between a supply voltage VDD and a supply reference voltage VSS. In some embodiments, voltage VBLEQ is equal to a supply voltage VDD/2. In some embodiments, voltage VBLEQ is equal to the supply voltage VDD. In some embodiments, voltage VBLEQ is equal to the supply reference voltage VSS. Other values of voltage VBLEQ are within the scope of various embodiments.

Pre-charge and equalization circuit 204 comprises transistors T1, T2 and T3.

In some embodiments, at least one or more of transistors T1, T2 or T3 is a P-type transistor. In some embodiments, at least one or more of transistors T1, T2 or T3 is a P-type field effect transistor (PFET). In some embodiments, at least one or more of transistors T1, T2 or T3 is a P-type metal oxide semiconductor (PMOS).

Transistors T2 and T3 are a pre-charge circuit. Transistors T2 and T3 are configured to pre-charge bit line BL and bit line bar BLB to voltage VBLEQ in response to signal BLEQ2. PMOS transistor T1 is an equalization circuit. Transistor T1 is configured to equalize the voltage of the bit line BL and the voltage of the bit line bar BLB in response to signal BLEQ1. In some embodiments, transistor T1 is configured to equalize the voltage of the bit line BL and the voltage of the bit line bar BLB to voltage VBLEQ in response to signal BLEQ1.

Gates of transistors T2 and T3 are coupled together, and are configured to receive signal BLEQ2. In some embodiments, signal BLEQ2 is a pre-charge signal.

Drains/sources of transistors T2 and T3 are coupled with bit line BL and bit line bar BLB, respectively. Sources/drains of transistors T2 and T3 are coupled together and are configured to receive voltage VBLEQ. In some embodiments, voltage VBLEQ is a supply voltage.

In some embodiments, when signal BLEQ2 is applied with a low logical value, transistors T2 and T3 are turned on, and pull corresponding bit line BL and bit line bar BLB to the supply voltage VBLEQ. As a result, the bit line BL and bit line bar BLB are pre-charged to the supply voltage VBLEQ.

Transistor T1 is coupled between the bit line BL and the bit line bar BLB. A gate of transistor T1 is configured to receive signal BLEQ1. In some embodiments, signal BLEQ1 is an equalization signal.

A drain/source of transistor T1 is coupled with the bit line BL. A source/drain of transistor T1 is coupled with the bit line bar BLB. In some embodiments, when signal BLEQ1 is applied with a low logical value, transistor T1 is turned on, and electrically couples the bit line BL and the bit line bar BLB together. As a result, the voltage of the bit line BL and the voltage of the bit line bar BLB are equalized. In some embodiments, the voltage of the bit line BL and the voltage of the bit line bar BLB are equalized to the supply voltage VBLEQ. In some embodiments, the source/drain and the drain/source of one or more transistors in the present disclosure are used interchangeably.

Other configurations, numbers of transistor or types of transistors in pre-charge and equalization circuit 204 are within the scope of the present disclosure. For example, other circuits and/or other types of transistors or quantities of transistors, are used to pre-charge and/or equalize bit line BL and bit line bar BLB are within the scope of various embodiments.

In some embodiments, a random input offset voltage is a large noise component for bit-line sense amplifiers thereby affecting the accuracy of one or more read operations of the memory cell. In some embodiments, the random input offset voltage is due to process variations, and/or asymmetry (e.g., random mismatches).

In some embodiments, by including the isolation transistor T4 between the capacitor C1 and the bit line BL, or by including the isolation transistor T8 between the capacitor C2 and the bit line bar BLB, the random offset of the input voltage to memory circuit 200 can be reduced and/or cancelled while improving the accuracy and speed of one or more read operations performed by memory circuit 200 and/or sense amplifier 202 compared with other approaches.

In some embodiments, by including the isolation transistor T4 between the capacitor C1 and the bit line BL, or by including the isolation transistor T8 between the capacitor C2 and the bit line bar BLB, during a read operation of memory cell SC, the voltage of node Nd2 (signal BL_IN) is boosted by the voltage Vsig thereby reducing and/or cancelling the random offset of the input voltage to memory circuit 200, while improving the accuracy and speed of one or more read operations performed by memory circuit 200 and/or sense amplifier 202 compared with other approaches.

Other configurations of memory circuit 200 are within the scope of the present disclosure.

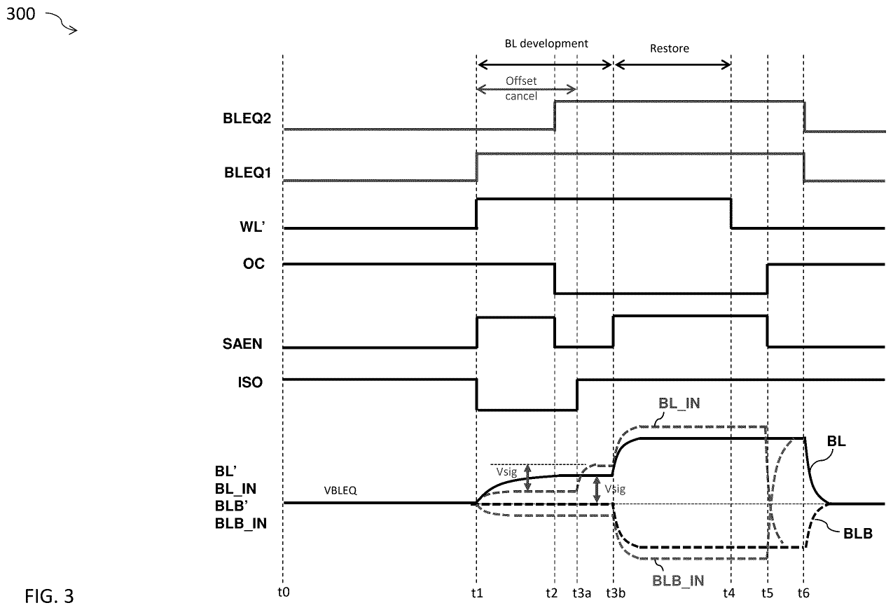

FIG. 3 is a timing diagram 300 of waveforms of a memory circuit, such as memory circuit 200 in FIG. 2, in accordance with some embodiments.

In some embodiments, FIG. 3 is a timing diagram 300 of memory circuit 100 of FIG. 1, in accordance with some embodiments.

In some embodiments, one or more read operations and/or write operations of the memory banks in at least memory circuit 100 of FIG. 1 are applied to at least one of memory partition 102A, 102B, 102C or 102D, and timing diagram 300 corresponds to waveforms during the read operations and write operations of at least one of memory partition 102A, 102B, 102C or 102D.

In some embodiments, one or more read operations and/or write operations are applied to memory cell SC in at least memory circuit 200 of FIG. 2, and timing diagram 300 corresponds to waveforms during the read operations and/or write operations of memory cell SC in memory circuit 200 of FIG. 2.

Timing diagram 300 includes waveforms of signal BLEQ2, signal BLEQ1, word line signal WL′, control signal OC, sense amplifier enable signal SAEN, isolation control signal ISO, bit line voltage BL′, bit line bar voltage BLB′, signal BL_IN and signal BLB_IN.

At time t0, the signal BLEQ2 is logically low, the signal BLEQ1 is logically low, the word line signal WL′ is logically low, the control signal OC is logically high, the sense amplifier enable signal SAEN is logically low, the isolation control signal ISO is logically high, the bit line voltage BL′ is equal to voltage VBLEQ, the bit line bar voltage BLB′ is equal to voltage VBLEQ, the signal BL_IN is equal to voltage VBLEQ, and the signal BLB_IN is equal to voltage VBLEQ.

At time t0, in response to the signal BLEQ2 being logically low, transistors T2 and T3 are turned on.

At time t0, in response to the isolation control signal ISO being logically high, transistors T4, T5, T7 and T8 are turned on.

For example, at time t0, in response to transistor T4 being turned on, node Nd1 is coupled to the bit line BL. For example, at time T0, in response to transistor T2 being turned on, and node Nd1 being coupled to the bit line BL, transistor T2 is configured to pre-charge bit line voltage BL′ to voltage VBLEQ.

For example, at time t0, in response to transistor T8 being turned on, node Nd4 is coupled to the bit line bar BLB. In response to transistor T3 being turned on, and node Nd4 being coupled to the bit line bar BLB, transistor T3 is configured to pre-charge the bit line bar voltage BLB′ to voltage VBLEQ.

At time t0, in response to the signal BLEQ1 being logically low, transistor T1 is turned on and configured to equalize the voltages of the bit line BL and the bit line bar BLB to voltage VBLEQ.

At time t0, in response to the word line signal WL′ being logically low, transistor T10 is turned off, and memory cell SC is decoupled from the bit line BL.

At time t0, in response to the control signal OC being logically low, transistor T6 is turned on thereby electrically coupling nodes Nd2 and Nd3 to each other, and transistor T9 is turned on thereby electrically coupling nodes Nd5 and Nd6 to each other.

For example, at time t0, in response to nodes Nd2 and Nd3 being coupled to each other, and transistor T5 being turned on, node Nd2 (signal BL_IN) is electrically coupled to the bit line bar BLB and is pre-charged to voltage VBLEQ.

For example, at time t0, in response to nodes Nd5 and Nd6 being coupled to each other, and transistor T7 being turned on, node Nd5 (signal BLB_IN) is electrically coupled to the bit line BL and is pre-charged to voltage VBLEQ.

At time t0, in response to the sense amplifier enable signal SAEN being logically low, inverters I1 and I2 of the sense amplifier 202 are turned off.

Between time t1 and time t6, a read operation is performed on memory cell SC.

Between time t1 and time t3a is referred to as the offset cancellation phase of memory circuit 200.

Between time t1 and time t3b is referred to as the bit line development phase of memory circuit 200.

Between time t3b and time t4 is referred to as the restore phase of memory circuit 200.

At time t1, the signal BLEQ1, the word line signal WL′ and the sense amplifier enable signal SAEN transition from logically low to logically high.

For example, at time t1, in response to at least the transition from logically low to logically high of signal BLEQ1 turns off transistor T1 thereby decoupling the bit line BL and the bit line bar BLB from each other.

For example, at time t1, in response to at least the transition from logically low to logically high of the word line signal WL′ turns on transistor T10 thereby coupling the bit line BL and the memory cell SC together. In some embodiments, at time t1, by coupling the bit line BL and the memory cell SC together, the data (e.g., Vsig) stored in memory cell SC is transferred to the bit line BL thereby causing the bit line voltage BL′ to be increased by voltage Vsig. In some embodiments, the data stored in memory cell SC is voltage Vsig. In this example, the data (e.g., Vsig) stored in memory cell SC is a logical 1. In some embodiments, the data (e.g., Vsig) stored in memory cell SC is a logical 0.

For example, at time t1, in response to at least the transition from logically low to logically high of the sense amplifier enable signal SAEN turns on inverters I1 and I2. At time t1, in response to inverter I1 turning on, causes signal BL_IN to be equal to a threshold voltage Vth1 of inverter I1. At time t1, in response to inverter I2 turning on, causes signal BLB_IN to be equal to a threshold voltage Vth2 of inverter I2.

At time t1, the isolation control signal ISO transitions from logically high to logically low. In response to at least the transition from logically high to logically low of the isolation control signal ISO turns off transistors T4, T5, T7 and T8. For example, at time t1, in response to turning off transistors T4 and T7, thereby causes corresponding nodes Nd1 and Nd6 to be electrically decoupled from the bit line BL. For example, at time t1, in response to turning off transistors T5 and T8, thereby causes corresponding nodes Nd3 and Nd4 to be electrically decoupled from the bit line bar BLB. In some embodiments, at time t1, since the transistors T4, T5, T7 and T8 are turned off, the inverters I1 and I2 are electrically isolated from the bit line BL and bit line bar BLB.

At time t2, the control signal OC and the sense amplifier enable signal SAEN transition from logically high to logically low.

For example, at time t2, in response to at least the transition from logically high to logically low of the sense amplifier enable signal SAEN turns off inverters I1 and I2.

For example, at time t2, in response to at least the transition from logically high to logically low of the control signal OC, transistor T6 is turned off thereby electrically decoupling nodes Nd2 and Nd3 from each other, and transistor T9 is turned off thereby electrically decoupling nodes Nd5 and Nd6 from each other.

In some embodiments, at time t2, the signals BL_IN and BLB_IN are able to settle by being electrically isolated from the bit line BL and bit line bar BLB thus allowing the offset cancellation process to be implemented by memory circuit 200.

In some embodiments, between time t1 to t3a, capacitor C1 is configured to store the offset of inverter I1, and capacitor C2 is configured to store the offset of inverter I2 thus allowing memory circuit 200 to account for the offset and thereby implementing the offset cancellation process.

In some embodiments, offset of memory circuit 200 or 500 is caused by manufacturing process variations, and asymmetry (e.g., random mismatches). In some embodiments, the offset is reduced and/or cancelled by memory circuit 200 or 500.

At time t2, the signal BLEQ2 transitions from logically low to logically high.

For example, at time t2, in response to at least the transition from logically low to logically high of signal BLEQ2 turns off transistors T2 and T3 thereby decoupling voltage VBLEQ from nodes Nd1 and Nd4.

At time t3a, the isolation control signal ISO transitions from logically low to logically high. In response to at least the transition from logically low to logically high of the isolation control signal ISO turns on transistors T4, T5, T7 and T8. For example, at time t3a, in response to turning on transistors T4 and T7, thereby causes corresponding nodes Nd1 and Nd6 to be electrically coupled to the bit line BL. In some embodiments, at time t3a, by electrically coupling node Nd1 to the bit line BL, then the voltage of node ND1 is equal to the bit line voltage BL′. In some embodiments, at time t3a, the bit line voltage BL′ is equal to a sum of the voltage VBLEQ and the voltage Vsig, thus causing signal BL_IN (which was equal to the threshold voltage Vth1 of inverter I1 at time T2) to be boosted by the capacitor C1 by voltage Vsig. In some embodiments, at time t3a, signal BL_IN is equal to a sum of voltage Vsig and the threshold voltage Vth1 of inverter I1.

For example, at time t3a, in response to turning on transistors T5 and T8, thereby causes corresponding nodes Nd3 and Nd4 to be electrically coupled to the bit line bar BLB. In some embodiments, at time t3a, since the transistors T4, T5, T7 and T8 are turned on, the inverters I1 and I2 are no longer electrically isolated from the bit line BL and bit line bar BLB.

At time t3a, inverters I1 and I2 are disabled, and transistors T6 and T9 are turned off and the offset cancellation process is finished.

Between time t3a and t3b, signal BL_IN and signal BLB_IN are settled, and inverters I1 and I2 are disabled.

Between time t3a and t3b, transistors T4, T5, T7 and T8 are turned on and sense amplifier 202 is ready to sense the bit line BL.

At time t3b, the sense amplifier enable signal SAEN transitions from logically low to logically high.

For example, at time t3b, in response to at least the transition from logically low to logically high of the sense amplifier enable signal SAEN turns on inverters I1 and I2.

At time t3b, in response to inverters I1 and I2 turning on, the inverters I1 and I2 are configured to sense the voltage difference between the bit line voltage BL′ and the bit line bar voltage BLB′. At time t3b, in response to inverters I1 and I2 turning on, causes signal BL_IN and the bit line voltage BL′ to be pulled towards voltage supply VDD, and causes signal BLB_IN and the bit line bar voltage BLB′ to be pulled towards voltage supply VSS.

Between time t3b and t4, the bit line voltage BL′ is equal to the voltage supply VDD, and the bit line voltage BL′ is stored as data (e.g., logic 1) to the memory cell SC in a write back operation (labelled as “Restore” in FIG. 3).

At time t4, the word line signal WL′ transitions from logically high to logically low.

For example, at time t4, in response to at least the transition from logically high to logically low of the word line signal WL′ thereby turns off transistor T10 thus decoupling the bit line BL and the memory cell SC from each other.

At time t5, the sense amplifier enable signal SAEN transitions from logically high to logically low.

For example, at time t5, in response to at least the transition from logically high to logically low of the sense amplifier enable signal SAEN thereby turns off inverters I1 and I2.

At time t5, the control signal OC transitions from logically low to logically high.

For example, at time t5, in response to at least the transition from logically low to logically high of the control signal OC, transistor T6 is turned on thereby electrically coupling nodes Nd2 and Nd3 to each other, and transistor T9 is turned on thereby electrically coupling nodes Nd5 and Nd6 to each other.

In some embodiments, at time t5, by electrically coupling nodes Nd2 and Nd3 to each other thereby causes node Nd2 to be electrically coupled to the bit line bar BLB thus causing signal BL_IN to be pulled towards the bit line bar voltage BLB′ (e.g., VSS).

In some embodiments, at time t5, by electrically coupling nodes Nd5 and Nd6 to each other thereby causes node Nd5 to be electrically coupled to the bit line BL thus causing signal BLB_IN to be pulled towards the bit line voltage BL′ (e.g., VDD).

At time t6, the signal BLEQ1 and the signal BLEQ2 transition from logically high to logically low.

For example, at time t6, in response to at least the transition from logically high to logically low of signal BLEQ1 turns on transistor T1 thereby coupling the bit line BL and the bit line bar BLB to each other.

At time t6, the signal BLEQ2 transitions from logically high to logically low.

For example, at time t6, in response to at least the transition from logically high to logically low of signal BLEQ2 turns on transistors T2 and T3 thereby coupling voltage VBLEQ to nodes Nd1 and Nd4.

At time t6, transistor T2 is configured to pre-charge the bit line voltage BL′ to voltage VBLEQ thereby causing the bit line voltage BL′ to be pulled towards the voltage VBLEQ.

At time t6, transistor T3 is configured to pre-charge the bit line bar voltage BLB′ to voltage VBLEQ thereby causing the bit line voltage BL′ to be pulled towards the voltage VBLEQ.

In some embodiments, the transition from logically low to logically high of the control signal OC at time t5 occurs at different times. For example, in some embodiments, the transition from logically low to logically high of the control signal OC can occur at time t6 or after time t6.

In some embodiments, timing diagram 300 causes memory circuit 200 to achieve one or more benefits described herein including the details discussed herein.

Other configurations of timing diagram 300 are within the scope of the present disclosure.

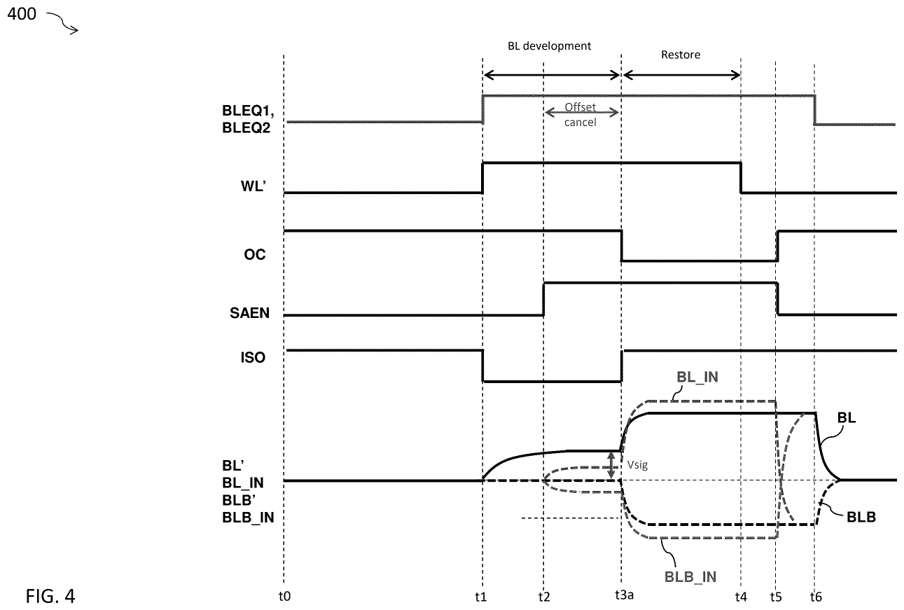

FIG. 4 is a timing diagram 400 of waveforms of a memory circuit, such as memory circuit 200 in FIG. 2, in accordance with some embodiments.

Timing diagram 400 is a variation of timing diagram 300 of FIG. 3, and similar detailed description is therefore omitted. For example, timing diagram 400 illustrates a non-limiting example where the sense amplifier enable signal SAEN has a single pulse in FIG. 4, whereas the sense amplifier enable signal SAEN of FIG. 3 has multiple pulses, and similar detailed description is therefore omitted.

In some embodiments, FIG. 4 is a timing diagram 400 of memory circuit 100 of FIG. 1, in accordance with some embodiments.

In some embodiments, one or more read operations and/or write operations of the memory banks in at least memory circuit 100 of FIG. 1 are applied to at least one of memory partition 102A, 102B, 102C or 102D, and timing diagram 400 corresponds to waveforms during the read operations and write operations of at least one of memory partition 102A, 102B, 102C or 102D.

In some embodiments, one or more read operations and/or write operations are applied to memory cell SC in at least memory circuit 200 of FIG. 2, and timing diagram 400 corresponds to waveforms during the read operations and/or write operations of memory cell SC in memory circuit 200 of FIG. 2.

Timing diagram 400 includes waveforms of signal BLEQ2, signal BLEQ1, word line signal WL′, control signal OC, sense amplifier enable signal SAEN, isolation control signal ISO, bit line voltage BL′, bit line bar voltage BLB′, signal BL_IN and signal BLB_IN.

At time t0, the signal BLEQ2 is logically low, the signal BLEQ1 is logically low, the word line signal WL′ is logically low, the control signal OC is logically high, the sense amplifier enable signal SAEN is logically low, the isolation control signal ISO is logically high, the bit line voltage BL′ is equal to voltage VBLEQ, the bit line bar voltage BLB′ is equal to voltage VBLEQ, the signal BL_IN is equal to voltage VBLEQ, and the signal BLB_IN is equal to voltage VBLEQ.

From time t0 to time t1 in FIGS. 3-4, the operation of memory circuit 200 in response to the timing diagram 400 is the same as the operation of memory circuit 200 in response to the timing diagram 300, and similar detailed description is therefore omitted.

In FIG. 4, between time t1 and time t6, a read operation is performed on memory cell SC.

In FIG. 4, between time t2 and time t3a is referred to as the offset cancellation phase of memory circuit 200.

In FIG. 4, between time t1 and time t3a is referred to as the bit line development phase of memory circuit 200.

In FIG. 4, between time t3a and time t4 is referred to as the restore phase of memory circuit 200.

In FIG. 4, at time t1, the signal BLEQ1, the signal BLEQ2 and the word line signal WL′ transition from logically low to logically high.

For example, at time t1, in response to at least the transition from logically low to logically high of signal BLEQ1 turns off transistor T1 thereby decoupling the bit line BL and the bit line bar BLB from each other.

For example, at time t1, in response to at least the transition from logically low to logically high of signal BLEQ2 turns off transistors T2 and T3 thereby decoupling voltage VBLEQ from nodes Nd1 and Nd4.

For example, at time t1, in response to at least the transition from logically low to logically high of the word line signal WL′ turns on transistor T10 thereby coupling the bit line BL and the memory cell SC together. In some embodiments, at time t1, by coupling the bit line BL and the memory cell SC together, the data (e.g., Vsig) stored in memory cell SC is transferred to the bit line BL thereby causing the bit line voltage BL′ to be increased by voltage Vsig. In this example, the data (e.g., Vsig) stored in memory cell SC is a logical 1. In some embodiments, the data (e.g., Vsig) stored in memory cell SC is a logical 0.

In FIG. 4, at time t1, the isolation control signal ISO transitions from logically high to logically low. In response to at least the transition from logically high to logically low of the isolation control signal ISO turns off transistors T4, T5, T7 and T8. For example, at time t1, in response to turning off transistors T4 and T7, thereby causes corresponding nodes Nd1 and Nd6 to be electrically decoupled from the bit line BL. For example, at time t1, in response to turning off transistors T5 and T8, thereby causes corresponding nodes Nd3 and Nd4 to be electrically decoupled from the bit line bar BLB.

In FIG. 4, at time t2, the sense amplifier enable signal SAEN transitions from logically low to logically high.

For example, at time t2 in FIG. 4, in response to at least the transition from logically low to logically high of the sense amplifier enable signal SAEN turns on inverters I1 and I2. At time t2 in FIG. 4, in response to inverter I1 turning on, causes signal BL_IN to be equal to a threshold voltage Vth1 of inverter I1. At time t2 in FIG. 4, in response to inverter I2 turning on, causes signal BLB_IN to be equal to a threshold voltage Vth2 of inverter I2. In some embodiments, the offset cancellation process implemented by memory circuit 200 begins at time t2 in response to the inverters I1 and I2 turning on, and the offset cancellation process ends at time t3a. In some embodiments, between time t2 to t3a of FIG. 4, capacitor C1 is configured to store the offset of inverter I1, and capacitor C2 is configured to store the offset of inverter I2 thus allowing memory circuit 200 to account for the offset and thereby implementing the offset cancellation process.

In FIG. 4, between time t2 and t3a, the signals BL_IN and BLB_IN are able to settle by being electrically isolated from the bit line BL and bit line bar BLB thus allowing the offset cancellation process to be implemented by memory circuit 200.

In some embodiments, at time t2 in FIG. 4, since the transistors T4, T5, T7 and T8 are turned off, the inverters I1 and I2 are electrically isolated from the bit line BL and bit line bar BLB.

In FIG. 4, at time t3a, the control signal OC transitions from logically high to logically low.

For example, at time t2, in response to at least the transition from logically high to logically low of the control signal OC, transistor T6 is turned off thereby electrically decoupling nodes Nd2 and Nd3 from each other, and transistor T9 is turned off thereby electrically decoupling nodes Nd5 and Nd6 from each other.

In FIG. 4, at time t3a, the isolation control signal ISO transitions from logically low to logically high. In response to at least the transition from logically low to logically high of the isolation control signal ISO turns on transistors T4, T5, T7 and T8. In some embodiments, at time t3a in FIG. 4, since the transistors T4, T5, T7 and T8 are turned on, the inverters I1 and I2 are no longer electrically isolated from the bit line BL and bit line bar BLB.

For example, at time t3a in FIG. 4, in response to turning on transistors T5 and T8, thereby causes corresponding nodes Nd3 and Nd4 to be electrically coupled to the bit line bar BLB.

For example, at time t3a in FIG. 4, in response to turning on transistors T4 and T7, thereby causes corresponding nodes Nd1 and Nd6 to be electrically coupled to the bit line BL. In some embodiments, at time t3a in FIG. 4, by electrically coupling node Nd1 to the bit line BL, then the voltage of node ND1 is equal to the bit line voltage BL′. In some embodiments, at time T3a in FIG. 4, the bit line voltage BL′ is equal to a sum of the voltage VBLEQ and the voltage Vsig, thus initially causing signal BL_IN to be boosted by the capacitor C1 by voltage Vsig. However, since the inverters I1 and I2 are already turned on at time t3a in FIG. 4, the inverters I1 and I2 are configured to sense the voltage difference between the bit line voltage BL′ and the bit line bar voltage BLB′ once the inverters I1 and I2 are no longer electrically isolated from the bit line BL and bit line bar BLB by isolation control signal ISO. At time t3a in FIG. 4, since inverters I1 and I2 are already turned on, thus causes signal BL_IN and the bit line voltage BL′ to be pulled towards voltage supply VDD, and causes signal BLB_IN and the bit line bar voltage BLB′ to be pulled towards voltage supply VSS.

In some embodiments, timing diagram 400 from time t3a to time t4 in FIG. 4 is the same as timing diagram 300 from time t3b to time t4 in FIG. 3, and similar detailed description is therefore omitted. In some embodiments, timing diagram 400 from time t4 to time t6 in FIG. 4 is the same as timing diagram 300 from time t4 to time t6 in FIG. 3, and similar detailed description is therefore omitted. In some embodiments, timing diagram 400 after time t6 in FIG. 4 is the same as timing diagram 300 after time t6 in FIG. 3, and similar detailed description is therefore omitted.

In some embodiments, the same timing diagrams for durations of time in FIG. 4 and FIG. 3, results in similar operation of memory circuit 200 for the durations of time in FIG. 4 and FIG. 3 where the timing diagrams are the same, and similar detailed description is therefore omitted.

In some embodiments, the transition from logically low to logically high of the control signal OC at time t5 occurs at different times. For example, in some embodiments, the transition from logically low to logically high of the control signal OC can occur at time t6 or after time t6.

In some embodiments, timing diagram 400 causes memory circuit 200 to achieve one or more benefits described herein including the details discussed herein.

Other configurations of timing diagram 400 are within the scope of the present disclosure.

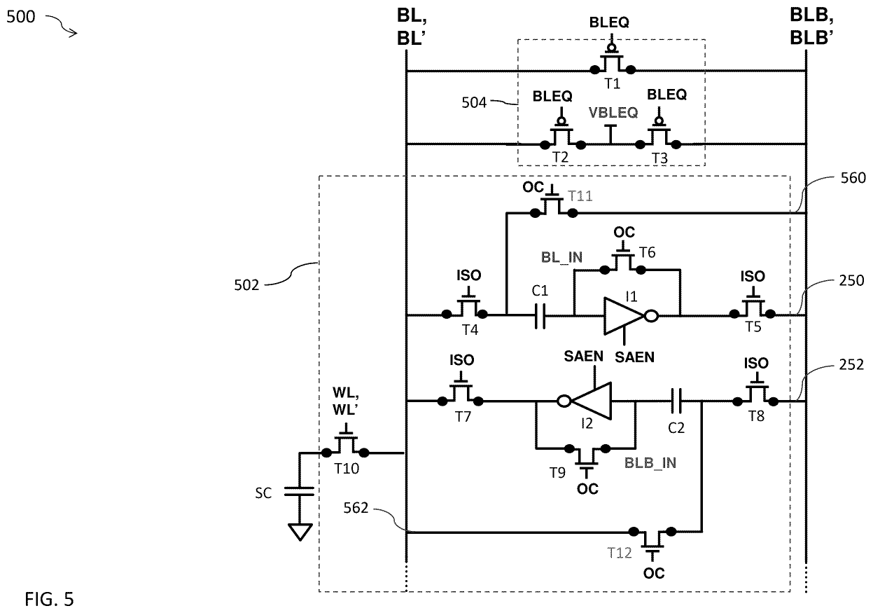

FIG. 5 is a circuit diagram of a memory circuit 500, in accordance with some embodiments.

Memory circuit 500 is a variation of memory circuit 200 of FIG. 2, and similar detailed description is therefore omitted. For example, memory circuit 500 illustrates a non-limiting example where node Nd1 and the first terminal of the capacitor C1 are coupled to the bit line bar BLB by a transistor T11 in FIG. 5, and node Nd4 and the first terminal of the capacitor C2 are coupled to the bit line BL by a transistor T12 in FIG. 5, and similar detailed description is therefore omitted.

Memory circuit 500 includes the memory cell SC, a sense amplifier circuit 502, the bit line BL, the bit line bar BLB, and a pre-charge and equalization circuit 504.

In comparison with memory circuit 200 of FIG. 2, sense amplifier circuit 502 of FIG. 5 replaces sense amplifier circuit 202, and similar detailed description is therefore omitted. In comparison with memory circuit 200 of FIG. 2, pre-charge and equalization circuit 504 of FIG. 5 replaces pre-charge and equalization circuit 504, and similar detailed description is therefore omitted.

Sense amplifier circuit 502 comprises transistor T4, transistor T5, transistor T6, transistor T7, transistor T8, transistor T9, transistor T10, a transistor T11, a transistor T12, capacitor C1, capacitor C2, inverter I1 and inverter I2.

In some embodiments, at least one or more of transistors T11 or T12 is an N-type transistor. In some embodiments, at least one or more of transistors T11 or T12 is an NFET. In some embodiments, at least one or more of transistors T11 or T12 is an NMOS transistor.

A gate of transistor T11 is configured to receive the control signal OC. In some embodiments, the gate of transistor T11 is coupled to the source of the control signal OC. Transistor T11 is enabled or disabled in response to the control signal OC. In some embodiments, when enabled, the transistor T11 electrically couples the bit line bar BLB and at least one of node ND1, the source/drain of transistor T4 or the first terminal of capacitor C1 together.

A source/drain of transistor T11 is coupled to the bit line bar BLB.

In FIG. 5, each of a drain/source of transistor T11, the node ND1, the source/drain of transistor T4 and the first terminal of capacitor C1 are coupled to each other.

In FIG. 5, each of the source/drain of transistor T11, the bit line bar BLB, the drain/source of transistor T5, the drain/source of transistor T8 and the source/drain of transistor T1 are coupled to each other.

A gate of transistor T12 is configured to receive the control signal OC. In some embodiments, the gate of transistor T12 is coupled to the source of the control signal OC. Transistor T12 is enabled or disabled in response to the control signal OC. In some embodiments, when enabled, the transistor T12 electrically couples the bit line BL and at least one of node ND4, the source/drain of transistor T8 or the first terminal of capacitor C2 together.

A source/drain of transistor T12 is coupled to the bit line BL.

In FIG. 5, each of a drain/source of transistor T12, the node ND4, the source/drain of transistor T8 and the first terminal of capacitor C2 are coupled to each other.

In FIG. 5, each of the source/drain of transistor T12, the bit line BL, the drain/source of transistor T4, the drain/source of transistor T7 and the drain/source of transistor T1 are coupled to each other.

In some embodiments, transistors T4 and T5, capacitor C1, inverter I1 and nodes Nd1, Nd2 and Nd3 are part of a first path 250. The first path 250 is coupled between the bit line BL and bit line bar BLB. In some embodiments, the first path 250 further includes transistor T6.

In some embodiments, transistors T7 and T8, capacitor C2, inverter I2 and nodes Nd4, Nd5 and Nd6 are part of a second path 252. The second path 252 is coupled between the bit line BL and bit line bar BLB. In some embodiments, the second path 252 further includes transistor T9.

In some embodiments, transistor T11 is part of a third path 560. The third path 560 is coupled between node Nd1 and the bit line bar BLB. In some embodiments, the third path 560 includes transistor T11.

In some embodiments, transistor T12 is part of a fourth path 562. The fourth path 562 is coupled between node Nd4 and the bit line BL. In some embodiments, the fourth path 562 includes transistor T12.

Pre-charge and equalization circuit 504 comprises transistors T1, T2 and T3.

In comparison with pre-charge and equalization circuit 204 of FIG. 2, signal BLEQ of FIG. 5 replaces signals BLEQ1 and BLEQ2 of FIG. 2, and similar detailed description is therefore omitted.

Gates of transistors T1, T2 and T3 are coupled together, and are configured to receive signal BLEQ. In some embodiments, signal BLEQ is a pre-charge signal and an equalization signal.

In some embodiments, when signal BLEQ is applied with a low logical value, transistors T1, T2 and T3 are turned on, and pull the bit line BL and bit line bar BLB to the supply voltage VBLEQ. As a result, the bit line BL and bit line bar BLB are pre-charged and equalized to the supply voltage VBLEQ.

In FIG. 5, the drain/source of transistor T2 is not directly coupled to node Nd1. In FIG. 5, the drain/source of transistor T2 is directly coupled to the bit line BL.

In FIG. 5, each of the drain/source of transistor T2, the source/drain of transistor T10, the drain/source of transistor T4, the drain/source of transistor T7, the drain/source of transistor T1 and the bit line BL are coupled to each other.

In FIG. 5, the drain/source of transistor T3 is not directly coupled to node Nd4. In FIG. 5, the drain/source of transistor T3 is directly coupled to the bit line bar BLB.

In FIG. 5, each of the drain/source of transistor T3, the drain/source of transistor T5, the drain/source of transistor T8, the source/drain of transistor T1 and the bit line bar BLB are coupled to each other.

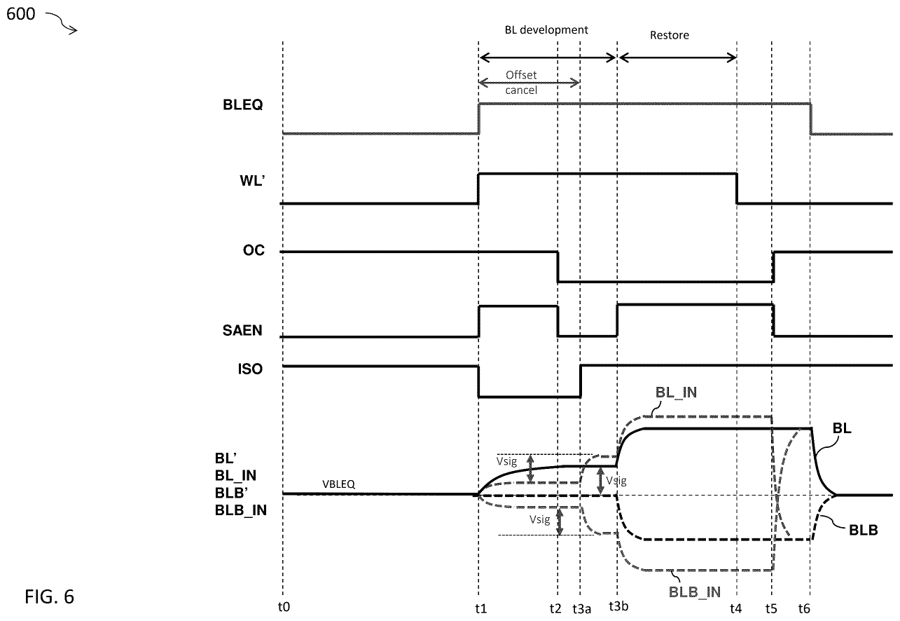

In some embodiments, by utilizing memory circuit 500, after time T3a (as shown in waveform 600 of FIG. 6), the voltage of node Nd5 (e.g., signal BLB_IN) is caused to be boosted towards reference voltage VSS by voltage Vsig.

In some embodiments, by utilizing memory circuit 500, after time T3a (as shown in waveform 600 of FIG. 6), signal BLB_IN is boosted towards reference voltage VSS by voltage Vsig thus increasing the difference between signal BLB_IN and signal BL_IN thereby improving the accuracy and speed of the read operation performed by memory circuit 500 and sense amplifier 502 compared with other approaches.

In some embodiments, memory circuit 500 is configured to perform offset cancellation during the BL development stage thereby resulting in no time penalty from performing offset cancellation by memory circuit 500 and thus improving the speed and accuracy of the read operation performed by memory circuit 500 and sense amplifier 502 compared with other approaches.

In some embodiments, memory circuit 500 operates to achieve one or more benefits described herein including the details discussed herein.

In some embodiments, by including the isolation transistor T4 between the capacitor C1 and the bit line BL, by including the isolation transistor T8 between the capacitor C2 and the bit line bar BLB, by including transistor T11 between node Nd1 and the bit line bar BLB, or by including transistor T12 between node Nd4 and the bit line BL, the random offset of the input voltage to memory circuit 500 can be reduced and/or cancelled while improving the accuracy and speed of one or more read operations performed by memory circuit 500 and/or sense amplifier 502 compared with other approaches.

In some embodiments, by including the isolation transistor T4 between the capacitor C1 and the bit line BL, or by including the isolation transistor T8 between the capacitor C2 and the bit line bar BLB, during a read operation of memory cell SC, the voltage of node Nd2 (signal BL_IN) is boosted by the voltage Vsig, and the voltage of node Nd5 (signal BLB_IN) is negatively boosted by the voltage Vsig, thereby reducing and/or cancelling the random offset of the input voltage to memory circuit 500, while improving the accuracy and speed of one or more read operations performed by memory circuit 500 and/or sense amplifier 502 compared with other approaches.

Other configurations of memory circuit 500 are within the scope of the present disclosure.

FIG. 6 is a timing diagram 600 of waveforms of a memory circuit, such as memory circuit 500 in FIG. 5, in accordance with some embodiments.

In some embodiments, FIG. 6 is a timing diagram 600 of memory circuit 100 of FIG. 1, in accordance with some embodiments.

In some embodiments, one or more read operations and/or write operations of the memory banks in at least memory circuit 100 of FIG. 1 are applied to at least one of memory partition 102A, 102B, 102C or 102D, and timing diagram 600 corresponds to waveforms during the read operations and write operations of at least one of memory partition 102A, 102B, 102C or 102D.

In some embodiments, one or more read operations and/or write operations are applied to memory cell SC in at least memory circuit 500 of FIG. 5, and timing diagram 600 corresponds to waveforms during the read operations and/or write operations of memory cell SC in memory circuit 500 of FIG. 5.

Timing diagram 600 includes waveforms of signal BLEQ, word line signal WL′, control signal OC, sense amplifier enable signal SAEN, isolation control signal ISO, bit line voltage BL′, bit line bar voltage BLB′, signal BL_IN and signal BLB_IN.

At time t0, the signal BLEQ is logically low, the word line signal WL′ is logically low, the control signal OC is logically high, the sense amplifier enable signal SAEN is logically low, the isolation control signal ISO is logically high, the bit line voltage BL′ is equal to voltage VBLEQ, the bit line bar voltage BLB′ is equal to voltage VBLEQ, the signal BL_IN is equal to voltage VBLEQ, and the signal BLB_IN is equal to voltage VBLEQ.

At time t0, in response to the signal BLEQ being logically low, transistors T1, T2 and T3 are turned on.

At time t0, in response to transistor T1 being turned on, transistor T1 is configured to equalize the voltages of the bit line BL and the bit line bar BLB to voltage VBLEQ.

At time t0, in response to the isolation control signal ISO being logically high, transistors T4, T5, T7 and T8 are turned on.

For example, at time t0, in response to transistor T4 being turned on, node Nd1 is coupled to the bit line BL. For example, at time T0, in response to transistor T2 being turned on, and node Nd1 being coupled to the bit line BL, transistor T2 is configured to pre-charge bit line voltage BL′ to voltage VBLEQ.

For example, at time t0, in response to transistor T8 being turned on, node Nd4 is coupled to the bit line bar BLB. In response to transistor T3 being turned on, and node Nd4 being coupled to the bit line bar BLB, transistor T3 is configured to pre-charge the bit line bar voltage BLB′ to voltage VBLEQ.

At time t0, in response to the word line signal WL′ being logically low, transistor T10 is turned off, and memory cell SC is decoupled from the bit line BL.

At time t0, in response to the control signal OC being logically low, transistor T6 is turned on thereby electrically coupling nodes Nd2 and Nd3 to each other, transistor T9 is turned on thereby electrically coupling nodes Nd5 and Nd6 to each other, transistor T11 is turned on thereby electrically coupling node Nd1 and the bit line bar BLB to each other, and transistor T12 is turned on thereby electrically coupling node Nd4 and the bit line BL to each other.

For example, at time t0, in response to nodes Nd2 and Nd3 being coupled to each other, and transistor T5 being turned on, node Nd2 (signal BL_IN) is electrically coupled to the bit line bar BLB and is pre-charged to voltage VBLEQ.

For example, at time t0, in response to nodes Nd5 and Nd6 being coupled to each other, and transistor T7 being turned on, node Nd5 (signal BLB_IN) is electrically coupled to the bit line BL and is pre-charged to voltage VBLEQ.

At time t0, in response to the sense amplifier enable signal SAEN being logically low, inverters I1 and I2 of the sense amplifier 202 are turned off.

In FIG. 6, between time t1 and time t6, a read operation is performed on memory cell SC.

In FIG. 6, between time t1 and time t3a is referred to as the offset cancellation phase of memory circuit 500.

In FIG. 6, between time t1 and time t3b is referred to as the bit line development phase of memory circuit 500.

In FIG. 6, between time t3b and time t4 is referred to as the restore phase of memory circuit 500.

At time t1, the signal BLEQ, the word line signal WL′ and the sense amplifier enable signal SAEN transition from logically low to logically high.

For example, at time t1, in response to at least the transition from logically low to logically high of signal BLEQ thereby turns off transistor T1.

For example, at time t1, in response to at least the transition from logically low to logically high of signal BLEQ thereby turns off transistors T2 and T3.

For example, at time t1, in response to at least the transition from logically low to logically high of the word line signal WL′ thereby turns on transistor T10 thereby coupling the bit line BL and the memory cell SC together. In some embodiments, at time t1, by coupling the bit line BL and the memory cell SC together, the data (e.g., Vsig) stored in memory cell SC is transferred to the bit line BL thereby causing the bit line voltage BL′ to be increased by voltage Vsig. In some embodiments, between at least time t1 and t2, the bit line voltage BL′ is equal to a sum of VBLEQ and Vsig (e.g., VBLEQ+Vsig). In this example, the data (e.g., Vsig) stored in memory cell SC is a logical 1. In some embodiments, the data (e.g., Vsig) stored in memory cell SC is a logical 0.

For example, at time t1, in response to at least the transition from logically low to logically high of the sense amplifier enable signal SAEN thereby turns on inverters I1 and I2. At time t1, in response to inverter I1 turning on, causes signal BL_IN to be equal to a threshold voltage Vth1 of inverter I1. At time t1, in response to inverter I2 turning on, causes signal BLB_IN to be equal to a threshold voltage Vth2 of inverter I2.

At time t1, the isolation control signal ISO transitions from logically high to logically low. In response to at least the transition from logically high to logically low of the isolation control signal ISO turns off transistors T4, T5, T7 and T8. For example, at time t1, in response to turning off transistors T4 and T7, thereby causes corresponding nodes Nd1 and Nd6 to be electrically decoupled from the bit line BL. For example, at time t1, in response to turning off transistors T5 and T8, thereby causes corresponding nodes Nd3 and Nd4 to be electrically decoupled from the bit line bar BLB. In some embodiments, at time t1, since the transistors T4, T5, T7 and T8 are turned off, the inverters I1 and I2 are electrically isolated from the bit line BL and bit line bar BLB.

At time t1, in response to turning off transistor T4, thereby causes node Nd1 to be electrically decoupled from the bit line BL, but node Nd1 is still electrically coupled to the bit line bar BLB by transistor T11 thereby causing the voltage of node Nd1 to be equal to the bit line bar voltage BLB′ (e.g., VBLEQ).

At time t1, in response to turning off transistor T8, thereby causes node Nd4 to be electrically decoupled from the bit line bar BLB, but node Nd4 is still electrically coupled to the bit line BL by transistor T12 thereby causing the voltage of node Nd4 to be equal to the bit line voltage BL′ (e.g., VBLEQ+Vsig).

At time t2, the control signal OC and the sense amplifier enable signal SAEN transition from logically high to logically low.

For example, at time t2, in response to at least the transition from logically high to logically low of the sense amplifier enable signal SAEN turns off inverters I1 and I2.

For example, at time t2, in response to at least the transition from logically high to logically low of the control signal OC, transistor T6 is turned off thereby electrically decoupling nodes Nd2 and Nd3 from each other, transistor T9 is turned off thereby electrically decoupling nodes Nd5 and Nd6 from each other, transistor T11 is turned off thereby electrically decoupling node Nd1 and the bit line bar BLB from each other, and transistor T12 is turned off thereby electrically decoupling node Nd4 and the bit line BL from each other.

In some embodiments, at time t2, the signals BL_IN and BLB_IN are able to settle by being electrically isolated from the bit line BL and bit line bar BLB thus allowing the offset cancellation process to be implemented by memory circuit 500.

In some embodiments, between time t1 to t3a, capacitor C1 is configured to store the offset of inverter I1, and capacitor C2 is configured to store the offset of inverter I2 thus allowing memory circuit 500 to account for the offset and thereby implementing the offset cancellation process.

At time t3a, the isolation control signal ISO transitions from logically low to logically high. In response to at least the transition from logically low to logically high of the isolation control signal ISO turns on transistors T4, T5, T7 and T8.

For example, at time t3a, in response to turning on transistors T4 and T7, thereby causes corresponding nodes Nd1 and Nd6 to be electrically coupled to the bit line BL. In some embodiments, at time t3a, by electrically coupling node Nd1 to the bit line BL, then the voltage of node ND1 is equal to the bit line voltage BL′ (e.g., VBLEQ+Vsig). In some embodiments, at time t3a, the bit line voltage BL′ is equal to a sum of the voltage VBLEQ and the voltage Vsig (VBLEQ+Vsig). Thus, at time t3a, the voltage of node Nd1 is increased by Vsig, thus causing signal BL_IN to be boosted by the capacitor C1 by voltage Vsig. In some embodiments, at time t3a, signal BL_IN is equal to a sum of voltage Vsig and the threshold voltage Vth1 of inverter I1. In some embodiments, at time t3 a, signal BL_IN is equal to Vth1+Vsig.

For example, at time t3a, in response to turning on transistors T5 and T8, thereby causes corresponding nodes Nd3 and Nd4 to be electrically coupled to the bit line bar BLB. In some embodiments, at time t3a, by electrically coupling node Nd4 to the bit line bar BLB, then the voltage of node Nd4 is changed to be equal to the bit line bar voltage BLB′. In some embodiments, at time t3a, the bit line bar voltage BLB′ is equal to the voltage VBLEQ. Between time t2 and t3a, the voltage of node Nd4 is equal to the sum of the voltage VBLEQ and the voltage Vsig (VBLEQ+Vsig). However, at time t3a, the voltage of node Nd4 is decreased by Vsig, thus causing signal BLB_IN to be negatively boosted by the capacitor C2 by voltage Vsig. In some embodiments, at time t3a, signal BLB_IN is equal to a difference between the threshold voltage Vth2 of inverter I2 and voltage Vsig. In some embodiments, at time t3a, signal BLB_IN is equal to Vth2−Vsig.

In some embodiments, as shown in FIG. 6, between at least time t3a and t3b, a differential voltage between signal BLB_IN and signal BLB_IN is a product of 2 times voltage Vsig thereby improving the accuracy and speed of the read operation performed by memory circuit 500 and sense amplifier 502 when compared with other approaches.

In some embodiments, between at least time t3a and t3b, the differential voltage between signal BLB_IN and signal BLB_IN is increased by at least voltage Vsig when compared to the waveform 300 in FIG. 3.

In some embodiments, at time t3a, since the transistors T4, T5, T7 and T8 are turned on, the inverters I1 and I2 are no longer electrically isolated from the bit line BL and bit line bar BLB.

At time t3a, inverters I1 and I2 are disabled, and transistors T6 and T9 are turned off and the offset cancellation process is finished.

Between time t3a and t3b, signal BL_IN and signal BLB_IN are settled, and inverters I1 and I2 are disabled.

Between time t3a and t3b, transistors T4, T5, T7 and T8 are turned on and sense amplifier 202 is ready to sense the bit line BL.

At time t3b, the sense amplifier enable signal SAEN transitions from logically low to logically high.

For example, at time t3b, in response to at least the transition from logically low to logically high of the sense amplifier enable signal SAEN turns on inverters I1 and I2.

At time t3b, in response to inverters I1 and I2 turning on, the inverters I1 and I2 are configured to sense the voltage difference between the bit line voltage BL′ and the bit line bar voltage BLB′. At time t3b, in response to inverters I1 and I2 turning on, causes signal BL_IN and the bit line voltage BL′ to be pulled towards voltage supply VDD, and causes signal BLB_IN and the bit line bar voltage BLB′ to be pulled towards voltage supply VSS.

Between time t3b and t4, the bit line voltage BL′ is equal to the voltage supply VDD, and the bit line voltage BL′ is stored as data (e.g., logic 1) to the memory cell SC in a write back operation (labelled as “Restore” in FIG. 6).

At time t4, the word line signal WL′ transitions from logically high to logically low.

For example, at time t4, in response to at least the transition from logically high to logically low of the word line signal WL′ thereby turns off transistor T10 thus decoupling the bit line BL and the memory cell SC from each other.

At time t5, the sense amplifier enable signal SAEN transitions from logically high to logically low.

For example, at time t5, in response to at least the transition from logically high to logically low of the sense amplifier enable signal SAEN thereby turns off inverters I1 and I2.

At time t5, the control signal OC transitions from logically low to logically high.

For example, at time t5, in response to at least the transition from logically low to logically high of the control signal OC, transistor T6 is turned on thereby electrically coupling nodes Nd2 and Nd3 to each other, and transistor T9 is turned on thereby electrically coupling nodes Nd5 and Nd6 to each other, transistor T11 is turned on thereby electrically coupling node Nd1 and the bit line bar BLB to each other, and transistor T12 is turned on thereby electrically coupling node Nd4 and the bit line BL to each other.

In some embodiments, at time t5, by electrically coupling nodes Nd2 and Nd3 to each other thereby causes node Nd2 to be electrically coupled to the bit line bar BLB thus causing signal BL_IN to be pulled towards the bit line bar voltage BLB′ (e.g., VSS).

In some embodiments, at time t5, by electrically coupling nodes Nd5 and Nd6 to each other thereby causes node Nd5 to be electrically coupled to the bit line BL thus causing signal BLB_IN to be pulled towards the bit line voltage BL′ (e.g., VDD).

At time t6, the signal BLEQ transitions from logically high to logically low.

For example, at time t6, in response to at least the transition from logically high to logically low of signal BLEQ turns on transistor T1 thereby coupling the bit line BL and the bit line bar BLB to each other.

For example, at time t6, in response to at least the transition from logically high to logically low of signal BLEQ turns on transistors T2 and T3 thereby coupling voltage VBLEQ to nodes Nd1 and Nd4.

At time t6, transistor T2 is configured to pre-charge the bit line voltage BL′ to voltage VBLEQ thereby causing the bit line voltage BL′ to be pulled towards the voltage VBLEQ.

At time t6, transistor T3 is configured to pre-charge the bit line bar voltage BLB′ to voltage VBLEQ thereby causing the bit line voltage BL′ to be pulled towards the voltage VBLEQ.

In some embodiments, the transition from logically low to logically high of the control signal OC at time t5 occurs at different times. For example, in some embodiments, the transition from logically low to logically high of the control signal OC can occur at time t6 or after time t6.

In some embodiments, timing diagram 600 causes memory circuit 500 to achieve one or more benefits described herein including the details discussed herein.

Other configurations of timing diagram 600 are within the scope of the present disclosure.

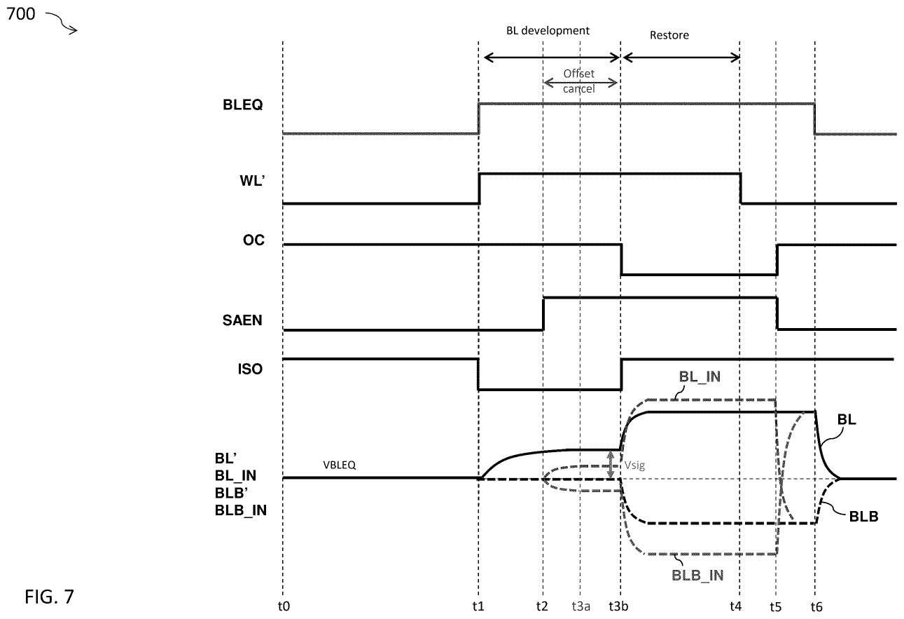

FIG. 7 is a timing diagram 700 of waveforms of a memory circuit, such as memory circuit 500 in FIG. 5, in accordance with some embodiments.

Timing diagram 700 is a variation of timing diagram 600 of FIG. 6, and similar detailed description is therefore omitted. For example, timing diagram 700 illustrates a non-limiting example where the sense amplifier enable signal SAEN has a single pulse in FIG. 7, whereas the sense amplifier enable signal SAEN of FIG. 6 has multiple pulses, and similar detailed description is therefore omitted.

In some embodiments, FIG. 7 is a timing diagram 700 of memory circuit 100 of FIG. 1, in accordance with some embodiments.

In some embodiments, one or more read operations and/or write operations of the memory banks in at least memory circuit 100 of FIG. 1 are applied to at least one of memory partition 102A, 102B, 102C or 102D, and timing diagram 700 corresponds to waveforms during the read operations and write operations of at least one of memory partition 102A, 102B, 102C or 102D.

In some embodiments, one or more read operations and/or write operations are applied to memory cell SC in at least memory circuit 500 of FIG. 5, and timing diagram 700 corresponds to waveforms during the read operations and/or write operations of memory cell SC in memory circuit 500 of FIG. 5.

Timing diagram 700 includes waveforms of signal BLEQ, word line signal WL′, control signal OC, sense amplifier enable signal SAEN, isolation control signal ISO, bit line voltage BL′, bit line bar voltage BLB′, signal BL_IN and signal BLB_IN.

At time t0, the signal BLEQ is logically low, the word line signal WL′ is logically low, the control signal OC is logically high, the sense amplifier enable signal SAEN is logically low, the isolation control signal ISO is logically high, the bit line voltage BL′ is equal to voltage VBLEQ, the bit line bar voltage BLB′ is equal to voltage VBLEQ, the signal BL_IN is equal to voltage VBLEQ, and the signal BLB_IN is equal to voltage VBLEQ.

From time t0 to time t1 in FIGS. 6-7, the operation of memory circuit 500 in response to the timing diagram 700 is the same as the operation of memory circuit 500 in response to the timing diagram 600, and similar detailed description is therefore omitted.

In FIG. 7, between time t1 and time t6, a read operation is performed on memory cell SC.

In FIG. 7, between time t2 and time t3b is referred to as the offset cancellation phase of memory circuit 500.

In FIG. 7, between time t1 and time t3b is referred to as the bit line development phase of memory circuit 500.

In FIG. 7, between time t3b and time t4 is referred to as the restore phase of memory circuit 500.

In FIG. 7, at time t1, the signal BLEQ and the word line signal WL′ transition from logically low to logically high.

For example, at time t1, in response to at least the transition from logically low to logically high of signal BLEQ1 thereby turns off transistor T1.

For example, at time t1, in response to at least the transition from logically low to logically high of signal BLEQ turns off transistors T2 and T3.

For example, at time t1, in response to at least the transition from logically low to logically high of the word line signal WL′ thereby turns on transistor T10 thereby coupling the bit line BL and the memory cell SC together. In some embodiments, at time t1, by coupling the bit line BL and the memory cell SC together, the data (e.g., Vsig) stored in memory cell SC is transferred to the bit line BL thereby causing the bit line voltage BL′ to be increased by voltage Vsig. In some embodiments, between at least time t1 and t2, the bit line voltage BL′ is equal to a sum of VBLEQ and Vsig (e.g., VBLEQ+Vsig). In this example, the data (e.g., Vsig) stored in memory cell SC is a logical 1. In some embodiments, the data (e.g., Vsig) stored in memory cell SC is a logical 0.

In FIG. 7, at time t1, the isolation control signal ISO transitions from logically high to logically low. In response to at least the transition from logically high to logically low of the isolation control signal ISO turns off transistors T4, T5, T7 and T8. For example, at time t1, in response to turning off transistors T4 and T7, thereby causes corresponding nodes Nd1 and Nd6 to be electrically decoupled from the bit line BL. For example, at time t1, in response to turning off transistors T5 and T8, thereby causes corresponding nodes Nd3 and Nd4 to be electrically decoupled from the bit line bar BLB. In some embodiments, at time t1, since the transistors T4, T5, T7 and T8 are turned off, the inverters I1 and I2 are electrically isolated from the bit line BL and bit line bar BLB.

At time t1, in response to turning off transistor T4, thereby causes node Nd1 to be electrically decoupled from the bit line BL, but node Nd1 is still electrically coupled to the bit line bar BLB by transistor T11 thereby causing the voltage of node Nd1 to be equal to the bit line bar voltage BLB′ (e.g., VBLEQ).

At time t1, in response to turning off transistor T8, thereby causes node Nd4 to be electrically decoupled from the bit line bar BLB, but node Nd4 is still electrically coupled to the bit line BL by transistor T12 thereby causing the voltage of node Nd4 to be equal to the bit line voltage BL′ (e.g., VBLEQ+Vsig).

In FIG. 7, at time t2, the sense amplifier enable signal SAEN transitions from logically low to logically high.

For example, at time t2, in response to at least the transition from logically low to logically high of the sense amplifier enable signal SAEN thereby turns on inverters I1 and I2. At time t1, in response to inverter I1 turning on, causes signal BL_IN to be equal to a threshold voltage Vth1 of inverter I1. At time t1, in response to inverter I2 turning on, causes signal BLB_IN to be equal to a threshold voltage Vth2 of inverter I2.

In some embodiments, the offset cancellation process implemented by memory circuit 200 begins at time t2 in response to the inverters I1 and I2 turning on, and the offset cancellation process ends at time t3b. In some embodiments, between time t2 to t3b of FIG. 7, capacitor C1 is configured to store the offset of inverter I1, and capacitor C2 is configured to store the offset of inverter I2 thus allowing memory circuit 500 to account for the offset and thereby implementing the offset cancellation process.

In FIG. 7, between time t2 and t3b, the signals BL_IN and BLB_IN are able to settle by being electrically isolated from the bit line BL and bit line bar BLB thus allowing the offset cancellation process to be implemented by memory circuit 500.

In some embodiments, at time t2 in FIG. 7, since the transistors T4, T5, T7 and T8 are turned off, the inverters I1 and I2 are electrically isolated from the bit line BL and bit line bar BLB.

In FIG. 7, at time t3b, the control signal OC transitions from logically high to logically low.

For example, at time t3b, in response to at least the transition from logically high to logically low of the control signal OC, transistor T6 is turned off thereby electrically decoupling nodes Nd2 and Nd3 from each other, and transistor T9 is turned off thereby electrically decoupling nodes Nd5 and Nd6 from each other, transistor T11 is turned off thereby electrically decoupling node Nd1 and the bit line bar BLB from each other, and transistor T12 is turned off thereby electrically decoupling node Nd4 and the bit line BL from each other.

In FIG. 7, at time t3b, the isolation control signal ISO transitions from logically low to logically high. In response to at least the transition from logically low to logically high of the isolation control signal ISO turns on transistors T4, T5, T7 and T8. In some embodiments, at time t3b in FIG. 7, since the transistors T4, T5, T7 and T8 are turned on, the inverters I1 and I2 are no longer electrically isolated from the bit line BL and bit line bar BLB.

For example, at time t3b in FIG. 7, in response to turning on transistors T4 and T7, thereby causes corresponding nodes Nd1 and Nd6 to be electrically coupled to the bit line BL.

In some embodiments, at time t3b in FIG. 7, by electrically coupling node Nd1 to the bit line BL, then the voltage of node ND1 is equal to the bit line voltage BL′ (e.g., VBLEQ+Vsig). In some embodiments, at time t3b in FIG. 7, the bit line voltage BL′ is equal to a sum of the voltage VBLEQ and the voltage Vsig (VBLEQ+Vsig). Thus, at time t3b in FIG. 7, the voltage of node Nd1 is increased by Vsig, thus causing signal BL_IN to be boosted by the capacitor C1 by voltage Vsig. In some embodiments, at time t3a, signal BL_IN is equal to a sum of voltage Vsig and the threshold voltage Vth1 of inverter I1. In some embodiments, at time t3b in FIG. 7, signal BL_IN is equal to Vth1+Vsig.

For example, at time t3b in FIG. 7, in response to turning on transistors T5 and T8, thereby causes corresponding nodes Nd3 and Nd4 to be electrically coupled to the bit line bar BLB. In some embodiments, at time t3b in FIG. 7, by electrically coupling node Nd4 to the bit line bar BLB, then the voltage of node Nd4 is changed to be equal to the bit line bar voltage BLB′. In some embodiments, at time t3b in FIG. 7, the bit line bar voltage BLB′ is equal to the voltage VBLEQ. Between time t2 and t3a, the voltage of node Nd4 is equal to the sum of the voltage VBLEQ and the voltage Vsig (VBLEQ+Vsig). However, at time t3b in FIG. 7, the voltage of node Nd4 is decreased by Vsig, thus causing signal BLB_IN to be negatively boosted by the capacitor C2 by voltage Vsig. In some embodiments, at time t3b in FIG. 7, signal BLB_IN is equal to a difference between the threshold voltage Vth2 of inverter I2 and voltage Vsig. In some embodiments, at time t3a, signal BLB_IN is equal to Vth2−Vsig.

However, since the inverters I1 and I2 are already turned on at time t3b in FIG. 7, the inverters I1 and I2 are configured to sense the voltage difference between the bit line voltage BL′ and the bit line bar voltage BLB′ once the inverters I1 and I2 are no longer electrically isolated from the bit line BL and bit line bar BLB by isolation control signal ISO. At time t3b in FIG. 7, since inverters I1 and I2 are already turned on, thus causes signal BL_IN and the bit line voltage BL′ to be pulled towards voltage supply VDD, and causes signal BLB_IN and the bit line bar voltage BLB′ to be pulled towards voltage supply VSS.

In some embodiments, as shown in FIG. 7, between at least time t3a and t3b, a differential voltage between signal BLB_IN and signal BLB_IN is a product of 2 times voltage Vsig thereby improving the accuracy and speed of the read operation performed by memory circuit 500 and sense amplifier 502 when compared with other approaches.

In some embodiments, between at least time t3a and t3b, the differential voltage between signal BLB_IN and signal BLB_IN is increased by at least voltage Vsig when compared to the waveform 300 in FIG. 3.

In some embodiments, at time t3b, since the transistors T4, T5, T7 and T8 are turned on, the inverters I1 and I2 are no longer electrically isolated from the bit line BL and bit line bar BLB.

At time t3b, inverters I1 and I2 are enabled, and transistors T6 and T9 are turned off and the offset cancellation process is finished.

At time t3b, transistors T4, T5, T7 and T8 are turned on and sense amplifier 202 is ready to sense the bit line BL.

Between time t3b and t4, the bit line voltage BL′ is equal to the voltage supply VDD, and the bit line voltage BL′ is stored as data (e.g., logic 1) to the memory cell SC in a write back operation (labelled as “Restore” in FIG. 7).

In some embodiments, timing diagram 700 from time t3b to time t4 in FIG. 7 is the same as timing diagram 600 from time t3b to time t4 in FIG. 6, and similar detailed description is therefore omitted. In some embodiments, timing diagram 700 from time t4 to time t6 in FIG. 7 is the same as timing diagram 600 from time t4 to time t6 in FIG. 6, and similar detailed description is therefore omitted. In some embodiments, timing diagram 700 after time t6 in FIG. 7 is the same as timing diagram 600 after time t6 in FIG. 6, and similar detailed description is therefore omitted.

In some embodiments, the same timing diagrams for durations of time in FIG. 7 and FIG. 6, results in similar operation of memory circuit 500 for the durations of time in FIG. 7 and FIG. 6 where the timing diagrams are the same, and similar detailed description is therefore omitted.

In some embodiments, the transition from logically low to logically high of the control signal OC at time t5 occurs at different times. For example, in some embodiments, the transition from logically low to logically high of the control signal OC can occur at time t6 or after time t6.

In some embodiments, timing diagram 700 causes memory circuit 200 to achieve one or more benefits described herein including the details discussed herein.

Other configurations of timing diagram 700 are within the scope of the present disclosure.

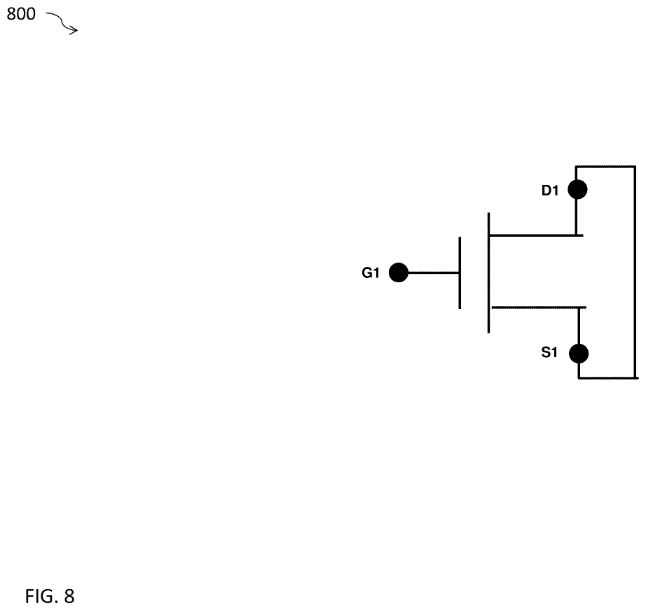

FIG. 8 is a circuit diagram of a circuit 800 usable in FIGS. 1, 2 and 5, in accordance with some embodiments.

In some embodiments, circuit 800 is usable as at least one of capacitor C1 or C2 of FIG. 2 or FIG. 5, and similar detailed description is therefore omitted. In some embodiments, circuit 800 is usable as memory cell SC of FIG. 2 or FIG. 5, and similar detailed description is therefore omitted. In some embodiments, circuit 800 is usable as one or more memory cells 112 of FIG. 1, and similar detailed description is therefore omitted.

Circuit 800 includes a transistor 802. In some embodiments, transistor 802 is an N-type transistor. In some embodiments, transistor 802 is an NFET. In some embodiments, transistor 802 is an NMOS transistor. Other transistor types or numbers of transistors in transistor 802 are within the scope of the present disclosure.

Transistor 802 is a capacitor coupled transistor. In some embodiments, transistor 802 is referred to as a MOSCAP.

Each of a source terminal S1 and a drain terminal D1 of transistor 802 are coupled to each other.

In some embodiments, the source terminal S1 and the drain terminal D1 of transistor 802 correspond to at least one of a first terminal of capacitor C1, a first terminal of capacitor C2 or a first terminal of memory cell SC, and a gate terminal G1 of transistor 802 corresponds to at least one of a second terminal of capacitor C1, a second terminal of capacitor C2 or a second terminal of memory cell SC, and similar detailed description is therefore omitted.

In some embodiments, the source terminal S1 and the drain terminal D1 of transistor 802 correspond to at least one of a second terminal of capacitor C1, a second terminal of capacitor C2 or a second terminal of memory cell SC, and the gate terminal G1 of transistor 802 corresponds to at least one of a first terminal of capacitor C1, a first terminal of capacitor C2 or a first terminal of memory cell SC, and similar detailed description is therefore omitted.

Other configurations of circuit 800 are within the scope of the present disclosure.

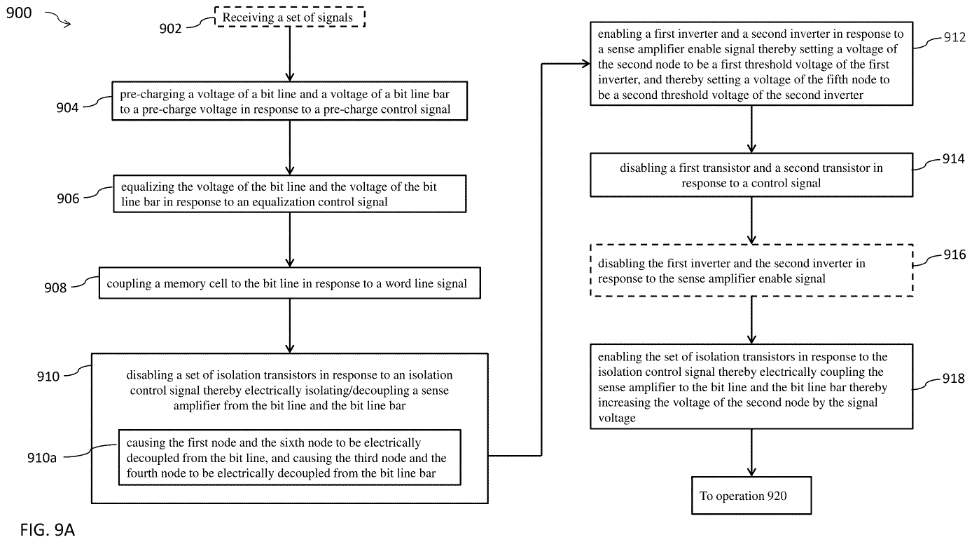

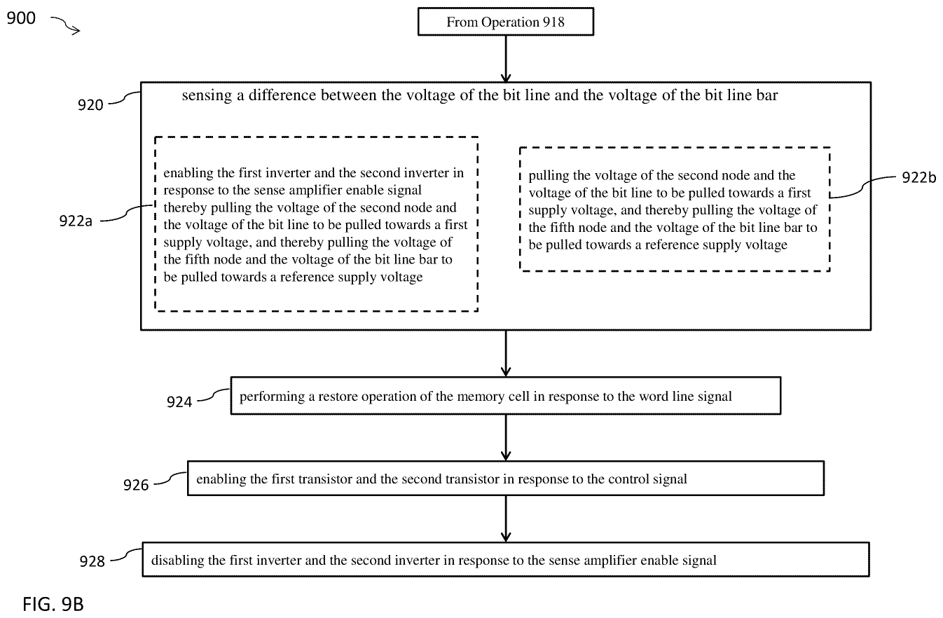

FIGS. 9A-9B are a flowchart of a method 900 of operating a circuit, in accordance with some embodiments.

In some embodiments, FIGS. 9A-9B are flowcharts of a method 900 of operating at least one of memory circuit 100 of FIG. 1, memory circuit 200 of FIG. 2 or circuit 800 of FIG. 8, and similar detailed description is omitted for brevity.

In some embodiments, FIGS. 9A-9B are flowcharts of a method 900 of operating a memory circuit, and the method 900 includes the features of timing diagrams 300 of FIG. 3 and timing diagram 400 of FIG. 4, and similar detailed description is omitted for brevity.

It is understood that additional operations may be performed before, during, and/or after the method 900 depicted in FIGS. 9A-9B, and that some other operations may only be briefly described herein. It is understood that method 900 utilizes features of one or more of least one of memory circuit 100 of FIG. 1, memory circuit 200 of FIG. 2 or circuit 800 of FIG. 8, and similar detailed description is omitted for brevity.

In some embodiments, other order of operations of method 900 is within the scope of the present disclosure. Method 900 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of method 900 is not performed.

In some embodiments, one or more operations in FIGS. 9A-9B shown with dashed lines are optionally performed.

In operation 902 of method 900, a set of signals are received.

In some embodiments, the set of signals of method 900 includes at least one of a word line signal WL′, a sense amplifier enable signal SAEN, an isolation control signal ISO, a control signal OC, a pre-charge control signal BLEQ2 or an equalization control signal BLEQ1.

In some embodiments, the word line signal WL′ is received by transistor T10.

In some embodiments, the sense amplifier enable signal SAEN is received by inverters I1 and I2.

In some embodiments, the isolation control signal ISO is received by transistors T4, T5, T7 and T8.

In some embodiments, the control signal OC is received by transistors T6 and T9.

In some embodiments, the pre-charge control signal BLEQ2 is received by transistors T2 and T3.

In some embodiments, the equalization control signal BLEQ1 is received by transistor T1.

In operation 904 of method 900, a voltage of a bit line BL and a voltage of a bit line bar BLB is pre-charged by a pre-charge circuit to a pre-charge voltage in response to a pre-charge control signal BLEQ2.

In some embodiments, the voltage of the bit line BL of method 900 or 1000 includes at least the bit line voltage BL′. In some embodiments, the voltage of the bit line bar BLB of method 900 includes at least the bit line bar voltage BLB′. In some embodiments, the pre-charge voltage of method 900 or 1000 includes at least voltage VBLEQ.

In some embodiments, the pre-charge circuit of method 900 includes at least pre-charge and equalization circuit 204. In some embodiments, the pre-charge circuit of method 900 includes at least one of transistor T2 or T3.

In some embodiments, the pre-charge circuit of method 900 is configured to pre-charge nodes Nd1 and Nd4 of FIG. 2 to the pre-charge voltage.

In operation 906 of method 900, the voltage of the bit line and the voltage of the bit line bar are equalized by an equalization circuit in response to an equalization control signal BLEQ1.

In some embodiments, the equalization circuit of method 900 includes at least pre-charge and equalization circuit 204. In some embodiments, the equalization circuit of method 900 includes at least one of transistor T1. In some embodiments, the equalization circuit is coupled between the bit line and the bit line bar.

In operation 908 of method 900, a memory cell SC is coupled by a pass-gate transistor to the bit line in response to the word line signal WL′.

In some embodiments, operation 908 of method 900 or 1000 further includes reading out datum stored in the memory cell to the bit line thus increasing or adjusting the voltage of the bit line by a signal voltage that corresponds to the datum stored in the memory cell.

In some embodiments, the pass-gate transistor of method 900 or 1000 includes at least transistor T10.

In some embodiments, the signal voltage of method 900 or 1000 includes at least voltage Vsig.

In operation 910 of method 900, a set of isolation transistors is disabled in response to the isolation control signal ISO thereby electrically isolating/decoupling a sense amplifier from the bit line and the bit line bar.

In some embodiments, the set of isolation transistors of method 900 or 1000 includes at least one of transistor T4, T5, T7 or T8.

In some embodiments, the sense amplifier of method 900 includes at least sense amplifier 202.

In some embodiments, the sense amplifier of method 900 or 1000 includes a first path 250 and a second path 252. In some embodiments, the first path 250 includes a first node (e.g., node Nd1), a second node (e.g., node Nd2) and a third node (e.g., node Nd3). In some embodiments, the second path 252 includes a fourth node (e.g., node Nd4), a fifth node (e.g., node Nd5) and a sixth node (e.g., node Nd6).

In some embodiments, operation 910 includes operation 910a.

In operation 910a of method 900, the set of isolation transistors is disabled in response to the isolation control signal ISO thereby causing the first node (e.g., node Nd1) and the sixth node (e.g., node Nd6) to be electrically decoupled from the bit line, and thereby causing the third node (e.g., node Nd3) and the fourth node (e.g., node Nd4) to be electrically decoupled from the bit line bar.

In operation 912 of method 900, a first inverter and a second inverter are enabled in response to the sense amplifier enable signal thereby setting a voltage BL_IN of the second node (e.g., node Nd2) to be a first threshold voltage of the first inverter, and thereby setting a voltage BLB_IN of the fifth node (e.g.,, node Nd5) to be a second threshold voltage of the second inverter.

In some embodiments, the first inverter of method 900 or 1000 includes one of inverter I1 or I2, and the second inverter of method 900 or 1000 includes another of inverter I2 or I1.

In some embodiments, the first threshold voltage of the first inverter of method 900 or 1000 includes one of threshold voltage Vth1 or Vth2, and the second threshold voltage of the second inverter of method 900 or 1000 includes another of threshold voltage Vth2 or Vth1.

In some embodiments, the first inverter and the second inverter of method 900 are part of sense amplifier 202.

In some embodiments, operation 912 occurs at time t1 in FIG. 3 or at time t2 in FIG. 4.

In operation 914 of method 900, a first transistor and a second transistor are disabled in response to the control signal OC.

In some embodiments, the first transistor is coupled in parallel with the first inverter, and the second transistor is coupled in parallel with the second inverter.

In some embodiments, the first transistor of method 900 or 1000 includes transistor T6.

In some embodiments, the second transistor of method 900 or 1000 includes transistor T9.

In operation 916 of method 900, the first inverter and the second inverter are disabled in response to the sense amplifier enable signal SAEN.

In some embodiments, operation 916 occurs at time t2 in FIG. 3.

In operation 918 of method 900, the set of isolation transistors is enabled in response to the isolation control signal ISO thereby electrically coupling the sense amplifier to the bit line and the bit line bar thereby increasing the voltage BL_IN of the second node (e.g. node Nd2) by the signal voltage.

In operation 920 of method 900, a difference between the voltage of the bit line and the voltage of the bit line bar is sensed by the sense amplifier.

In some embodiments, operation 920 of method 900 or 1000 further includes operation 922a or 922b.

In some embodiments, operation 920 of method 900 further includes operation 922a when memory circuit 200 is configured to utilize timing diagram 300 of FIG. 3, and similar detailed description is therefore omitted.

In some embodiments, operation 920 of method 900 further includes operation 922b when memory circuit 200 is configured to utilize timing diagram 400 of FIG. 4 and similar detailed description is therefore omitted.

In operation 922a of method 900, the first inverter and the second inverter are enabled in response to the sense amplifier enable signal SAEN thereby pulling the voltage BL_IN of the second node (e.g., node Nd2) and the voltage of the bit line to be pulled towards a first supply voltage (e.g., supply voltage VDD), and thereby pulling the voltage BLB_IN of the fifth node (e.g., node Nd5) and the voltage of the bit line bar to be pulled towards a reference supply voltage (e.g., reference supply voltage VSS).

In some embodiments, operation 922a occurs at time t3b in FIG. 3.

In operation 922b of method 900, the voltage BL_IN of the second node (e.g., node Nd2) and the voltage of the bit line are pulled towards a first supply voltage (e.g., supply voltage VDD), and the voltage BLB_IN of the fifth node (e.g., node Nd5) and the voltage of the bit line bar are pulled towards a reference supply voltage (e.g., reference supply voltage VSS).

In some embodiments, operation 922b occurs at time t3a in FIG. 4.

In operation 924 of method 900, a restore operation of memory cell SC is performed in response to the word line signal WL′.

In some embodiments, the restore operation of memory cell SC of method 900 or 1000 includes writing back the voltage supply VDD to memory cell SC in a write back operation (labelled as “Restore” in FIGS. 3, 6 and 7) between time t3b and t4.

In some embodiments, the restore operation of memory cell SC of method 900 or 1000 includes writing back the voltage supply VDD to memory cell SC in a write back operation (labelled as “Restore” in FIG. 4) between time t3a and t4.

In operation 926 of method 900, the first transistor and the second transistor are enabled in response to the control signal OC.

In operation 928 of method 900, the first inverter and the second inverter are disabled in response to the sense amplifier enable signal SAEN.

In some embodiments, after operation 928, method 900 returns to operations 904 and/or 906.

In some embodiments, while method 900 is described with respect to timing diagram 300 applied to memory circuit 200, method 900 also utilizes timing diagram 400 applied to memory circuit 200 in a similar manner and is not described for brevity, but one or more operations of method 900 are not performed. For example, in these embodiments, when method 900 utilizes timing diagram 400 as applied to memory circuit 200, then method 900 includes one or more of operations 902, 904, 906, 908, 910, 910a, 912, 914, 918, 920, 922b, 924, 926 or 928, and similar detailed description is omitted for brevity.

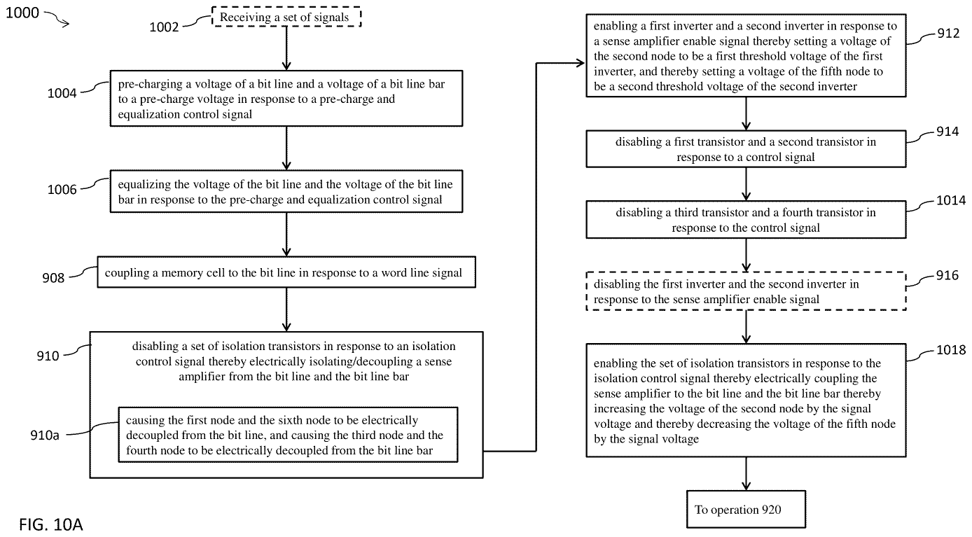

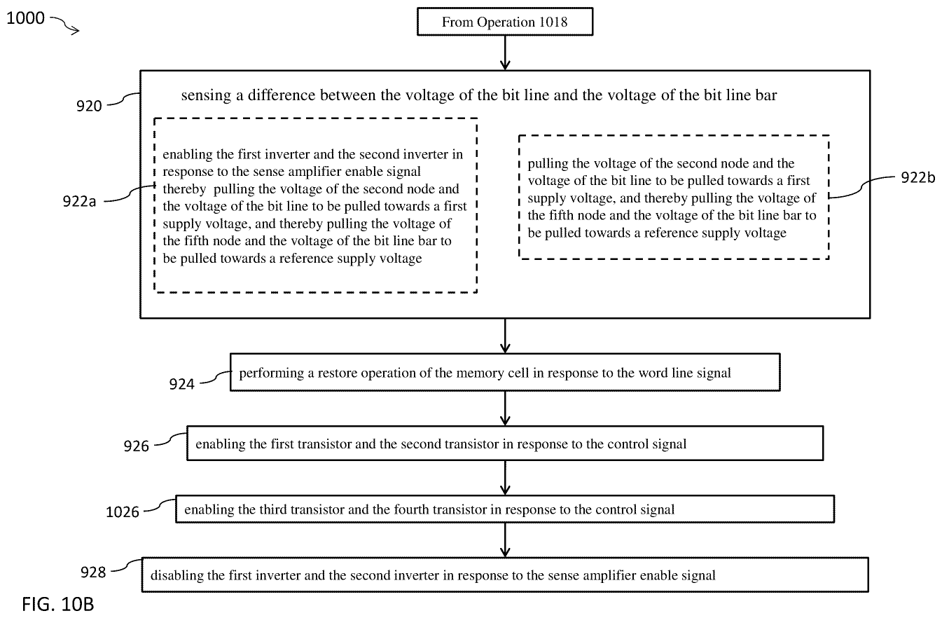

FIGS. 10A-10B are a flowchart of a method 1000 of operating a circuit, in accordance with some embodiments.

In some embodiments, FIGS. 10A-10B are flowcharts of a method 1000 of operating at least one of memory circuit 100 of FIG. 1, memory circuit 500 of FIG. 5 or circuit 800 of FIG. 8, and similar detailed description is omitted for brevity.

In some embodiments, FIGS. 10A-10B are flowcharts of a method 1000 of operating a memory circuit, and the method 1000 includes the features of timing diagram 600 of FIG. 6 and timing diagram 700 of FIG. 7, and similar detailed description is omitted for brevity.

It is understood that additional operations may be performed before, during, and/or after the method 1000 depicted in FIGS. 10A-10B, and that some other operations may only be briefly described herein. It is understood that method 1000 utilizes features of one or more of least one of memory circuit 100 of FIG. 1, memory circuit 500 of FIG. 5 or circuit 800 of FIG. 8, and similar detailed description is omitted for brevity.

In some embodiments, other order of operations of method 1000 is within the scope of the present disclosure. Method 1000 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of method 1000 is not performed.

In some embodiments, one or more operations in FIGS. 10A-10B shown with dashed lines are optionally performed.

In some embodiments, one or more operations of method 1000 includes one or more operations from method 900, and similar detailed description is omitted for brevity.

In operation 1002 of method 1000, a set of signals are received.

In some embodiments, the set of signals of method 1000 includes at least one of a word line signal WL′, a sense amplifier enable signal SAEN, an isolation control signal ISO, a control signal OC or a pre-charge and equalization control signal BLEQ.

In some embodiments, the word line signal WL′ is received by transistor T10.

In some embodiments, the sense amplifier enable signal SAEN is received by inverters I1 and I2.

In some embodiments, the isolation control signal ISO is received by transistors T4, T5, T7 and T8.

In some embodiments, the control signal OC is received by transistors T6, T9, T11 and T12.

In some embodiments, the pre-charge and equalization control signal BLEQ1 is received by transistors T1, T2 and T3.

In operation 1004 of method 1000, a voltage of a bit line BL and a voltage of a bit line bar BLB is pre-charged by a pre-charge circuit to a pre-charge voltage in response to the pre-charge and equalization control signal BLEQ.

In some embodiments, the voltage of the bit line BL of method 900 or 1000 includes at least the bit line voltage BL′. In some embodiments, the voltage of the bit line bar BLB of method 900 includes at least the bit line bar voltage BLB′. In some embodiments, the pre-charge voltage of method 900 or 1000 includes at least voltage VBLEQ.

In some embodiments, the pre-charge circuit of method 1000 includes at least pre-charge and equalization circuit 504. In some embodiments, the pre-charge circuit of method 1000 includes at least one of transistor T2 or T3.

In operation 1006 of method 1000, the voltage of the bit line and the voltage of the bit line bar are equalized by an equalization circuit in response to the pre-charge and equalization control signal BLEQ.

In some embodiments, the equalization circuit of method 1000 includes at least pre-charge and equalization circuit 504. In some embodiments, the equalization circuit of method 1000 includes at least one of transistor T1.

In operation 908 of method 1000, a memory cell SC is coupled by a pass-gate transistor to the bit line in response to the word line signal WL′.

In operation 910 of method 1000, a set of isolation transistors is disabled in response to the isolation control signal ISO thereby electrically isolating/decoupling a sense amplifier from the bit line and the bit line bar.

In some embodiments, the sense amplifier of method 1000 includes at least sense amplifier 502.

In some embodiments, operation 910 includes operation 910a.

In operation 910a of method 1000, the set of isolation transistors is disabled in response to the isolation control signal ISO thereby causing the first node (e.g., node Nd1) and the sixth node (e.g., node Nd6) to be electrically decoupled from the bit line, and thereby causing the third node (e.g., node Nd3) and the fourth node (e.g., node Nd4) to be electrically decoupled from the bit line bar.

In operation 912 of method 1000, a first inverter and a second inverter are enabled in response to the sense amplifier enable signal thereby setting a voltage BL_IN of the second node (e.g., node Nd2) to be a first threshold voltage of the first inverter, and thereby setting a voltage BLB_IN of the fifth node (e.g.,, node Nd5) to be a second threshold voltage of the second inverter.

In some embodiments, the first inverter and the second inverter of method 1000 are part of sense amplifier 502.

In some embodiments, operation 912 occurs at time t1 in FIG. 6 or at time t2 in FIG. 7.

In operation 914 of method 1000, a first transistor and a second transistor are disabled in response to the control signal OC.

In some embodiments, the first transistor is coupled in parallel with the first inverter, and the second transistor is coupled in parallel with the second inverter.

In some embodiments, the first transistor of method 900 or 1000 includes transistor T6.

In some embodiments, the second transistor of method 900 or 1000 includes transistor T9.

In operation 1014 of method 1000, a third transistor and a fourth transistor are disabled in response to the control signal OC.

In some embodiments, operation 1014 further includes decoupling the first node and the bit line bar from each other, and decoupling the fourth node and the bit line from each other. In some embodiments, the third transistor is coupled between the first node and the bit line bar. In some embodiments, the fourth transistor is coupled between the fourth node and the bit line.

In some embodiments, the third transistor of method 1000 includes transistor T11.

In some embodiments, the fourth transistor of method 1000 includes transistor T12.

In some embodiments, operation 1014 occurs at time t2 in FIG. 6 or at time t3b in FIG. 7.

In operation 916 of method 1000, the first inverter and the second inverter are disabled in response to the sense amplifier enable signal SAEN.

In some embodiments, operation 916 occurs at time t2 in FIG. 6.

In operation 918 of method 1000, the set of isolation transistors is enabled in response to the isolation control signal ISO thereby electrically coupling the sense amplifier to the bit line and the bit line bar thereby increasing the voltage BL_IN of the second node (e.g. node Nd2) by the signal voltage, and thereby decreasing the voltage BLB_IN of the fifth node (e.g., node Nd5) by the signal voltage.

In operation 920 of method 1000, a difference between the voltage of the bit line and the voltage of the bit line bar is sensed by the sense amplifier.

In some embodiments, operation 920 of method 1000 further includes operation 922a or 922b.

In some embodiments, operation 920 of method 1000 further includes operation 922a when memory circuit 500 is configured to utilize timing diagram 600 of FIG. 6, and similar detailed description is therefore omitted.

In some embodiments, operation 920 of method 1000 further includes operation 922b when memory circuit 500 is configured to utilize timing diagram 700 of FIG. 7 and similar detailed description is therefore omitted.

In operation 922a of method 1000, the first inverter and the second inverter are enabled in response to the sense amplifier enable signal SAEN thereby pulling the voltage BL_IN of the second node (e.g., node Nd2) and the voltage of the bit line to be pulled towards a first supply voltage (e.g., supply voltage VDD), and thereby pulling the voltage BLB_IN of the fifth node (e.g., node Nd5) and the voltage of the bit line bar to be pulled towards a reference supply voltage (e.g., reference supply voltage VSS).

In some embodiments, operation 922a occurs at time t3b in FIG. 6.

In operation 922b of method 1000, the voltage BL_IN of the second node (e.g., node Nd2) and the voltage of the bit line are pulled towards a first supply voltage (e.g., supply voltage VDD), and the voltage BLB_IN of the fifth node (e.g., node Nd5) and the voltage of the bit line bar are pulled towards a reference supply voltage (e.g., reference supply voltage VSS).

In some embodiments, operation 922b occurs at time t3a in FIG. 7.

In operation 924 of method 1000, a restore operation of memory cell SC is performed in response to the word line signal WL′.

In some embodiments, the restore operation of memory cell SC of method 900 or 1000 includes writing back the voltage supply VDD to memory cell SC in a write back operation (labelled as “Restore” in FIGS. 3, 6 and 7) between time t3b and t4.

In some embodiments, the restore operation of memory cell SC of method 900 or 1000 includes writing back the voltage supply VDD to memory cell SC in a write back operation (labelled as “Restore” in FIG. 4) between time t3a and t4.

In operation 926 of method 1000, the first transistor and the second transistor are enabled in response to the control signal OC.

In operation 1026 of method 1000, the third transistor and the fourth transistor are enabled in response to the control signal OC.

In some embodiments, operation 1026 further includes coupling the first node and the bit line bar together, and coupling the fourth node and the bit line together.

In operation 928 of method 1000, the first inverter and the second inverter are disabled in response to the sense amplifier enable signal SAEN.

In some embodiments, after operation 928, method 1000 returns to operations 1004 and/or 1006.

In some embodiments, while method 1000 is described with respect to timing diagram 600 applied to memory circuit 500, method 1000 also utilizes timing diagram 700 applied to memory circuit 500 in a similar manner and is not described for brevity, but one or more operations of method 1000 are not performed. For example, in these embodiments, when method 1000 utilizes timing diagram 700 as applied to memory circuit 500, then method 1000 includes one or more of operations 1002, 1004, 1006, 908, 910, 910a, 912, 914, 1014, 1018, 920, 922b, 924, 926, 1026 or 928, and similar detailed description is omitted for brevity.

By operating method 900 or 1000, memory circuit 100, 200 or 500 operates to achieve one or more of the benefits discussed herein.

In some embodiments, one or more of the operations of method 900 or 1000 is not performed. Furthermore, various PMOS or NMOS transistors shown in FIGS. 2, 5 and 8 are of a particular dopant type (e.g., N-type or P-type) are for illustration purposes. Embodiments of the disclosure are not limited to a particular transistor type, and one or more of the PMOS or NMOS transistors shown in FIGS. 2, 5 and 8 can be substituted with a corresponding transistor of a different transistor/dopant type. Similarly, the low or high logical value of various signals used in the above description is also for illustration. Embodiments of the disclosure are not limited to a particular logical value when a signal is activated and/or deactivated. Selecting different logical values is within the scope of various embodiments. Selecting different numbers of inverters in FIGS. 2, 5 and 8 is within the scope of various embodiments. Selecting different numbers of transistors in FIGS. 2, 5 and 8 within the scope of various embodiments.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

One aspect of this description relates to a memory circuit. In some embodiments, the memory circuit includes a memory cell, a bit line, a bit line bar, and a pass-gate transistor coupled to the memory cell and the bit line. In some embodiments, the memory circuit further includes a sense amplifier coupled to the bit line, the bit line bar and the pass-gate transistor. In some embodiments, the sense amplifier includes a first path between the bit line and the bit line bar. In some embodiments, the first path includes a first isolation transistor configured to receive an isolation control signal, and being coupled between the bit line and a first node. In some embodiments, the first path further includes a first inverter configured to receive a sense amplifier enable signal, and being coupled between a second node and a third node. In some embodiments, the memory circuit further includes a pre-charge circuit coupled to the first node, and configured to pre-charge the first node to a pre-charge voltage in response to a pre-charge control signal.

Another aspect of this description relates to a memory circuit. In some embodiments, the memory circuit includes a memory cell, a bit line, a bit line bar, a word line, and a pass-gate transistor configured to receive a word line signal, and being coupled to the word line, the memory cell and the bit line. In some embodiments, the memory circuit further includes a sense amplifier coupled to the bit line, the bit line bar and the pass-gate transistor. In some embodiments, the sense amplifier includes a first path between the bit line and the bit line bar. In some embodiments, the first path includes a first isolation transistor configured to receive an isolation control signal, and being coupled between the bit line and a first node. In some embodiments, the first path further includes a first inverter configured to receive a sense amplifier enable signal, and being coupled between a second node and a third node. In some embodiments, the sense amplifier further includes a second path between the first node and the bit line bar. In some embodiments, the second path includes a first transistor configured to receive a control signal, and being coupled between the first node and the bit line bar. In some embodiments, the memory circuit further includes a pre-charge and equalization circuit coupled to the bit line and the bit line bar, and being configured to pre-charge a voltage of the bit line and the bit line bar to a pre-charge voltage in response to a pre-charge/equalization control signal.

Still another aspect of this description relates to a method of operating a memory circuit. In some embodiments, the method includes pre-charging, by a pre-charge circuit, a voltage of a bit line and a voltage of a bit line bar to a pre-charge voltage in response to a pre-charge control signal. In some embodiments, the method further includes coupling, by a pass-gate transistor, a memory cell to the bit line in response to a word line signal thereby reading out a datum stored in the memory cell to the bit line thus increasing the voltage of the bit line by a signal voltage that corresponds to the datum stored in the memory cell. In some embodiments, the method further includes disabling a set of isolation transistors in response to an isolation control signal thereby electrically decoupling a sense amplifier from the bit line and the bit line bar, the sense amplifier including a first path and a second path, the first path including a first node, a second node and a third node, and the second path including a fourth node, a fifth node and a sixth node. In some embodiments, the method further includes enabling a first inverter and a second inverter in response to a sense amplifier enable signal thereby setting a voltage of the second node to be a first threshold voltage of the first inverter, and thereby setting a voltage of the fifth node to be a second threshold voltage of the second inverter, the first inverter and the second inverter being part of the sense amplifier. In some embodiments, the method further includes disabling a first transistor and a second transistor in response to a control signal, the first transistor being coupled in parallel with the first inverter, and the second transistor being coupled in parallel with the second inverter. In some embodiments, the method further includes disabling the first inverter and the second inverter in response to the sense amplifier enable signal. In some embodiments, the method further includes enabling the set of isolation transistors in response to the isolation control signal thereby electrically coupling the sense amplifier to the bit line and the bit line bar thereby increasing the voltage of the second node by the signal voltage. In some embodiments, the method further includes sensing a difference between the voltage of the bit line and the voltage of the bit line bar.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit comprising:
a memory cell;
a bit line;
a bit line bar;
a pass-gate transistor coupled to the memory cell and the bit line;
a sense amplifier coupled to the bit line, the bit line bar and the pass-gate transistor, the sense amplifier comprising:
a first path between the bit line and the bit line bar, the first path comprising:
a first isolation transistor configured to receive an isolation control signal, and being coupled between the bit line and a first node; and
a first inverter configured to receive a sense amplifier enable signal, and being coupled between a second node and a third node; and
a pre-charge circuit coupled to the first node, and configured to pre-charge the first node to a pre-charge voltage in response to a pre-charge control signal.

2. The memory circuit of claim 1, wherein the first path further comprises:
a first capacitor coupled between the first node and the second node; and
a second isolation transistor configured to receive the isolation control signal, and being coupled between the third node and the bit line bar.

3. The memory circuit of claim 2, wherein the sense amplifier further comprises:
a second path between the bit line and the bit line bar, the second path comprising:
a third isolation transistor configured to receive the isolation control signal, and being coupled between the bit line bar and a fourth node; and
a second inverter configured to receive the sense amplifier enable signal, and coupled between a fifth node and a sixth node,
wherein the pre-charge circuit is further coupled to the fourth node, and further configured to pre-charge the fourth node to the pre-charge voltage in response to the pre-charge control signal.

4. The memory circuit of claim 3, wherein the second path further comprises:
a second capacitor coupled between the fourth node and the fifth node; and
a fourth isolation transistor configured to receive the isolation control signal, and being coupled between the sixth node and the bit line.

5. The memory circuit of claim 4, wherein the sense amplifier further comprises:
a first transistor configured to receive a control signal, being coupled in parallel with the first inverter, and being between the second node and the third node; and
a second transistor configured to receive the control signal, being coupled in parallel with the second inverter, and being between the fifth node and the sixth node.

6. The memory circuit of claim 4, wherein the pre-charge circuit comprises:
a first P-type transistor comprising:
a first terminal of the first P-type transistor being configured to receive the pre-charge control signal;
a second terminal of the first P-type transistor being coupled to the first node, the first isolation transistor and the first capacitor; and
a third terminal of the first P-type transistor being coupled to the pre-charge voltage; and
a second P-type transistor comprising:
a first terminal of the second P-type transistor being configured to receive the pre-charge control signal;
a second terminal of the second P-type transistor being coupled to the fourth node, the third isolation transistor and the second capacitor; and
a third terminal of the second P-type transistor being coupled to the pre-charge voltage and the third terminal of the first P-type transistor.

7. The memory circuit of claim 1, further comprising:
an equalization circuit configured to equalize a voltage of the bit line and a voltage of the bit line bar in response to an equalization control signal, the equalization circuit being coupled between the bit line and the bit line bar.

8. The memory circuit of claim 7, wherein the equalization circuit comprises:
a first P-type transistor comprising:
a first terminal of the first P-type transistor being configured to receive the equalization control signal;
a second terminal of the first P-type transistor being coupled to the bit line; and
a third terminal of the first P-type transistor being coupled to the bit line bar.

9. The memory circuit of claim 1, wherein the memory cell comprises:
a capacitor coupled between the pass-gate transistor and a reference voltage supply.

10. A memory circuit comprising:
a memory cell;
a bit line;
a bit line bar;
a word line;
a pass-gate transistor configured to receive a word line signal, and being coupled to the word line, the memory cell and the bit line;
a sense amplifier coupled to the bit line, the bit line bar and the pass-gate transistor, the sense amplifier comprising:
a first path between the bit line and the bit line bar, the first path comprising:
a first isolation transistor configured to receive an isolation control signal, and being coupled between the bit line and a first node; and
a first inverter configured to receive a sense amplifier enable signal, and being coupled between a second node and a third node; and
a second path between the first node and the bit line bar, the second path comprising:
a first transistor configured to receive a control signal, and being coupled between the first node and the bit line bar; and
a pre-charge and equalization circuit coupled to the bit line and the bit line bar, and being configured to pre-charge a voltage of the bit line and the bit line bar to a pre-charge voltage in response to a pre-charge/equalization control signal.

11. The memory circuit of claim 10, wherein the first path further comprises:
a first capacitor coupled between the first node and the second node; and
a second isolation transistor configured to receive the isolation control signal, and being coupled between the third node and the bit line bar.

12. The memory circuit of claim 11, wherein the sense amplifier further comprises:
a third path between the bit line and the bit line bar, the third path comprising:
a third isolation transistor configured to receive the isolation control signal, and being coupled between the bit line bar and a fourth node; and
a second inverter configured to receive the sense amplifier enable signal, and being coupled between a fifth node and a sixth node;
a second capacitor coupled between the fourth node and the fifth node; and
a fourth isolation transistor configured to receive the isolation control signal, and being coupled between the sixth node and the bit line.

13. The memory circuit of claim 12, wherein the sense amplifier further comprises:
a fourth path between the fourth node and the bit line, the fourth path comprising:
a second transistor configured to receive the control signal, and being coupled between the fourth node and the bit line.

14. The memory circuit of claim 13, wherein the sense amplifier further comprises:
a third transistor configured to receive the control signal, being coupled in parallel with the first inverter, and being between the second node and the third node; and
a fourth transistor configured to receive the control signal, being coupled in parallel with the second inverter, and being between the fifth node and the sixth node.

15. The memory circuit of claim 13, wherein the pre-charge and equalization circuit comprises:
a first P-type transistor comprising:
a first terminal of the first P-type transistor being configured to receive the pre-charge/equalization control signal;
a second terminal of the first P-type transistor being coupled to the bit line; and
a third terminal of the first P-type transistor being coupled to the pre-charge voltage; and
a second P-type transistor comprising:
a first terminal of the second P-type transistor being configured to receive the pre-charge/equalization control signal;
a second terminal of the second P-type transistor being coupled to the bit line bar; and
a third terminal of the second P-type transistor being coupled to the pre-charge voltage and the third terminal of the first P-type transistor.

16. The memory circuit of claim 10, wherein the pre-charge and equalization circuit is further configured to equalize the voltage of the bit line and the bit line bar in response to the pre-charge/equalization control signal.

17. The memory circuit of claim 10, wherein the pre-charge and equalization circuit further comprises:
a third P-type transistor comprising:
a first terminal of the third P-type transistor being configured to receive the pre-charge/equalization control signal;
a second terminal of the third P-type transistor being coupled to the bit line; and
a third terminal of the third P-type transistor being coupled to the bit line bar.

18. A method of operating a memory circuit, the method comprising:
pre-charging, by a pre-charge circuit, a voltage of a bit line and a voltage of a bit line bar to a pre-charge voltage in response to a pre-charge control signal;
coupling, by a pass-gate transistor, a memory cell to the bit line in response to a word line signal thereby reading out a datum stored in the memory cell to the bit line thus increasing the voltage of the bit line by a signal voltage that corresponds to the datum stored in the memory cell;
disabling a set of isolation transistors in response to an isolation control signal thereby electrically decoupling a sense amplifier from the bit line and the bit line bar, the sense amplifier including a first path and a second path, the first path including a first node, a second node and a third node, and the second path including a fourth node, a fifth node and a sixth node;
enabling a first inverter and a second inverter in response to a sense amplifier enable signal thereby setting a voltage of the second node to be a first threshold voltage of the first inverter, and thereby setting a voltage of the fifth node to be a second threshold voltage of the second inverter, the first inverter and the second inverter being part of the sense amplifier;
disabling a first transistor and a second transistor in response to a control signal, the first transistor being coupled in parallel with the first inverter, and the second transistor being coupled in parallel with the second inverter;
disabling the first inverter and the second inverter in response to the sense amplifier enable signal;
enabling the set of isolation transistors in response to the isolation control signal thereby electrically coupling the sense amplifier to the bit line and the bit line bar thereby increasing the voltage of the second node by the signal voltage; and
sensing a difference between the voltage of the bit line and the voltage of the bit line bar.

19. The method of claim 18, wherein
the disabling the set of isolation transistors in response to the isolation control signal thereby electrically decoupling the sense amplifier from the bit line and the bit line bar comprises:
causing the first node and the sixth node to be electrically decoupled from the bit line, and causing the third node and the fourth node to be electrically decoupled from the bit line bar;
the sensing the difference between the voltage of the bit line and the voltage of the bit line bar comprises:
enabling the first inverter and the second inverter in response to the sense amplifier enable signal thereby pulling the voltage of the second node and the voltage of the bit line to be pulled towards a first supply voltage, and thereby pulling the voltage of the fifth node and the voltage of the bit line bar to be pulled towards a reference supply voltage;

20. The method of claim 19, further comprising:
performing a restore operation of the memory cell in response to the word line signal;
enabling the first transistor and the second transistor in response to the control signal; and
disabling the first inverter and the second inverter in response to the sense amplifier enable signal.
